(19) United States
(12) Patent Application Publication
(10) Pub. No.: US 2025/0109159 A1
(43) Pub. Date: Apr. 3, 2025

(54) COMPOSITE MATERIAL, AND LIGHT-EMITTING DIODE AND PREPARATION METHOD THEREFOR

(71) Applicant: TCL TECHNOLOGY GROUP CORPORATION, Huizhou, Guangdong (CN)

(72) Inventor: Wenlin LIANG, Huizhou, Guangdong (CN)

(73) Assignee: TCL TECHNOLOGY GROUP CORPORATION, Huizhou, Guangdong (CN)

(21) Appl. No.: 18/713,175

(22) PCT Filed: Dec. 7, 2022
(86) PCT No.: PCT/CN2022/137212

§ 371 Date: May 24, 2024

(30) Foreign Application Priority Data
Dec. 17, 2021 (CN) 202111550075.3

(51) Int. Cl. C07F 15/00; H10K 50/115; H10K 50/14; H10K 50/805; H10K 71/60; H10K 85/30; H10K 102/20

(52) U.S. Cl. CPC C07F 15/0006; H10K 50/115; H10K 50/14; H10K 50/805; H10K 71/60; H10K 85/341; H10K 2102/20

(57) ABSTRACT

A composite material. and a light-emitting diode and a preparation method therefor. The composite material includes a carbolong compound and a heteromacrocyclic compound, wherein the molar ratio of the carbolong compound to the heteromacrocyclic compound is 1:1-3; the carbolong compound comprises anions and cations; and the heteromacrocyclic compound is selected from one of a substituted or unsubstituted heteroaromatic compound which has 6-20 annular atoms and is of a semi-ring structure, a substituted or unsubstituted heteroaromatic compound having 12-50 annular atoms, a dimer of a substituted or unsubstituted heteroaromatic compound having 12-50 annular atoms, and a trimer of a substituted or unsubstituted heteroaromatic compound having 12-50 annular atoms. The composite material can reduce the work function of an electrode, prolong the operating life of a device, and improve the performance of the device.

This application claims priority to Chinese Application No. 202111550075.3, entitled “COMPOSITE MATERIAL, AND LIGHT-EMITTING DIODE AND PREPARATION METHOD THEREFOR”, filed on Dec. 17, 2021. The entire disclosures of the above application are incorporated herein by reference.

### TECHNICAL FIELD

The present disclosure relates to a field of display technologies, and more particularly, to composite material, and light-emitting diode and preparation method therefor.

### BACKGROUND

The light-emitting diode (LED) is a device that emits energy by combining electrons and holes, encompassing various types such as organic light-emitting diodes, quantum dot light-emitting diodes, and inorganic light-emitting diodes. LED typically include “sandwich” structure comprising a stacked anode, functional layer, and cathode. The functional layer includes a light-emitting layer and a charge transport layer. Within the charge transport layer, the electron transport layer facilitates electron movement between the cathode and luminescent layer, while the hole transport layer enables hole transportation between the anode and luminescent layer.

In order to minimize the work function difference between the cathode and electron transport layers, conventional LED often employ low work function metals like copper or aluminum as cathode materials. However, these metals are prone to corrosion from water and oxygen due to their high reactivity in ambient conditions, thereby affecting device stability. On the other hand, using more stable metals such as gold or silver with higher work functions as cathode materials can lead to Schottky barriers formation at interfaces with electron transport materials. This hinders efficient electron transportation resulting in significantly reduced LED performance.

Similarly, when a stable and high-power function metal material is used for the anode, it is also easy to form a barrier with the material of the hole transport layer, hindering the hole transport, resulting in a reduction in the performance of the LED.

### Technical Solution

In view of this, the present disclosure provides a composite material, and a light-emitting diode and a preparation method therefor.

According to a first aspect, the present disclosure provides a composite material, comprising:
comprising:
a carbolong compound, comprising anions and cations; and
a heteromacrocyclic compound, selected from one of a substituted or unsubstituted heteroaromatic compound which has 6-20 annular atoms and is of a semi-ring structure, a substituted or unsubstituted heteroaromatic compound having 12-50 annular atoms, a dimer of a substituted or unsubstituted heteroaromatic compound having 12-50 annular atoms, and a trimer of a substituted or unsubstituted heteroaromatic compound having 12-50 annular atoms;
wherein the molar ratio of the carbolong compound to the heteromacrocyclic compound is 1:1-3.

Alternatively, the general chemical formula of the carbolong compound is:

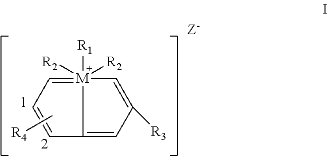

wherein in a general formula I, R₁ and R₃ are independently selected from one or more of —H, halogen, —SCN, cyanogroup, alkyl group with 1-20 carbon atoms, alkoxy group, alkylthio group, ester group, amide group, amine group, carboxyl group, substituted amide group having 2-20 carbon atoms, cycloalkyl group having 3-20 carbon atoms, substituted or unsubstituted aryl group, and substituted or unsubstituted alkenyl group having 2-20 carbon atoms, substituted or unsubstituted alkynyl group having 2-20 carbon atoms, an aryl oxygen group having 6-20 carbon atoms, and an aryl sulfur group having 6-20 carbon atoms;
R₂ is independently selected from one of the —H, quaternary phosphine groups having 3-30 carbon atoms, and pyridinyl groups having 6-7 carbon atoms;
R₄ is selected from one or more of substituted or unsubstituted aryl groups, substituted or unsubstituted alkenyl groups having 2-20 carbon atoms, substituted or unsubstituted alkynyl groups having 2-20 carbon atoms,

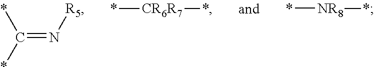

wherein, when the group represented by the R₄ contains two linking sites, the R₄ is ringed with two carbon atoms shown by 1 to 2 in formula I;
R₅, R₆, and R₇ are independently selected from one or more of —H, halogen, —SCN, cyanogroup, alkyl group having 1-20 carbon atoms, alkoxy group, alkylthio group, ester group, amide group, amine group, carboxyl group, substituted amide group having 2-20 carbon atoms, cycloalkyl group having 3-20 carbon atoms, substituted or unsubstituted aryl group, and substituted or unsubstituted aryl group having 2-20 carbon atoms One or more of alkenyl groups with carbon atoms, substituted or unsubstituted alkynyl groups having 2-20 carbon atoms, aryl oxygen groups having 6-20 carbon atoms, and aryl sulfur groups having 6-20 carbon atoms;
R₈ is selected from one or more of substituted or unsubstituted aryl groups, substituted or unsubstituted alkyl groups having 1-20 carbon atoms, and substituted or unsubstituted cycloalkyl groups having 3-20 carbon atoms;
R₁₅ is selected from one of substituted or unsubstituted alkyls, and substituted or unsubstituted ether groups;
M is selected from transition metal;
Z⁻ is an anion, which is specifically selected from one of BF⁻, OTf⁻, BF₄⁻, Cl⁻, Br⁻, F⁻, I⁻, CN⁻, and BrO₄⁻.

Alternatively, R₁ and R₃ are independently selected from one of —H, halogen, and —CO;
each time R₂ appears, it is independently selected from one of the —H, and —PPh₃;
R₄ is selected from one of

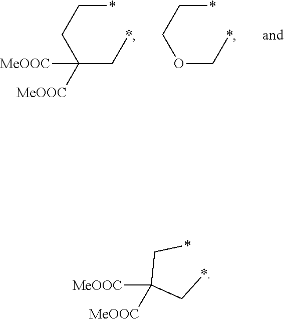

Alternatively, the transition metal is selected from one of iridium, osmium, and rhodium.

Alternatively, the heteromacrocyclic compound is m doubly symmetric compound, wherein m is an integer and m≥2.

Alternatively, the heteromacrocyclic compound include one or more heteroatoms selected from one of the nitrogen atoms, sulfur atoms, and oxygen atoms.

Alternatively, the chemical formula of heteromacrocyclic compound has one of the chemical formulas shown in formula II, III, IV, and V:

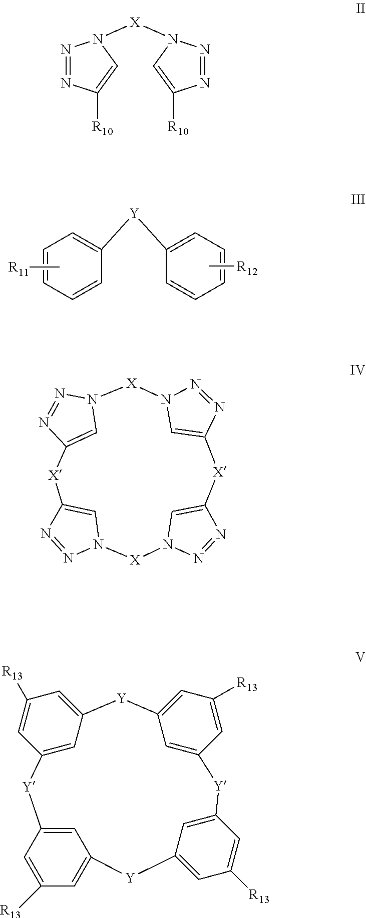

wherein the general fomular II to V, R₁₀ and R₁₃ are independently selected from one of —H, alkyl, alkoxy, and octyl-beta-d-thiopyranoside groups;
R₁₁ and R₁₂ are selected from one of —H, alkyl, alkoxy, and octyl-β-D-thiopyranoside groups; wherein R₁₁ and R₁₂ are the same group, and the connection of R₁₁ and R₁₂ makes Formula III symmetrical;
X and X′ are independently selected from one of substituted or unsubstituted aryl groups, and substituted or unsubstituted pyridine groups; and
Y is selected from one of the substituted or unsubstituted pyridine group, and

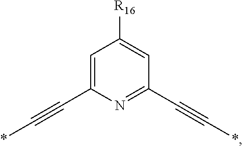

wherein R₁₆ is selected from one of —H, methoxy, and tert-butoxy groups;
Y′ is an alkyne group having two carbon atoms.

Alternatively, the alkyl groups in R₁₀, R₁₁, R₁₂ and R₁₃ are independently selected from one of methyl groups, and tert-butyl groups; and
the alkoxy groups in R₁₀, R₁₁, R₁₂ and R₁₃ are independently selected from one of the methoxy, and tert-butoxy groups.

Alternatively, the X and X′ are selected from one of

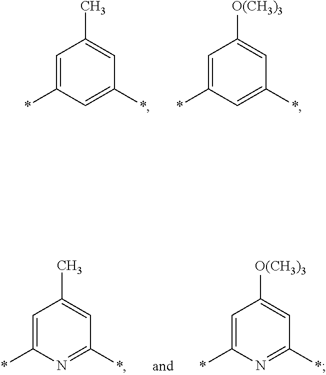

and
Y is selected from one of

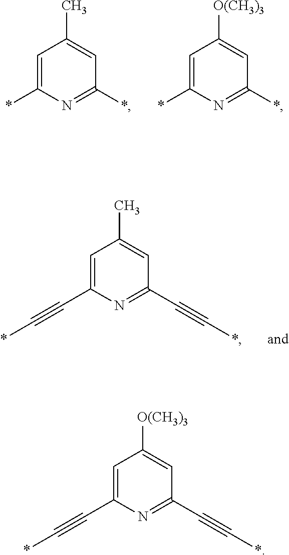

Alternatively, the carbolong compound is selected from one of

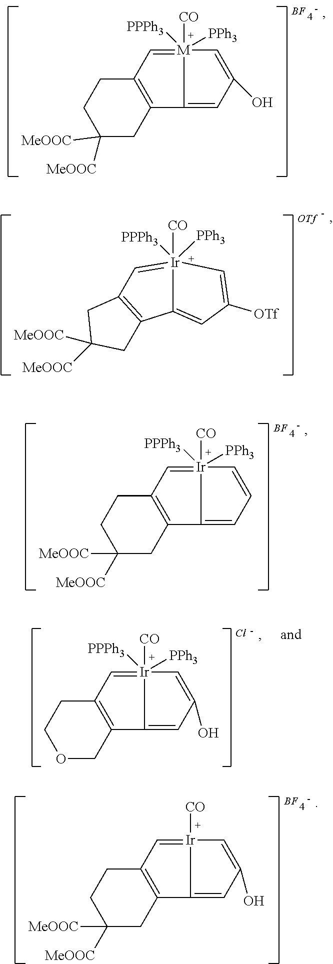

Alternatively, the heteromacrocyclic compound is selected from one of

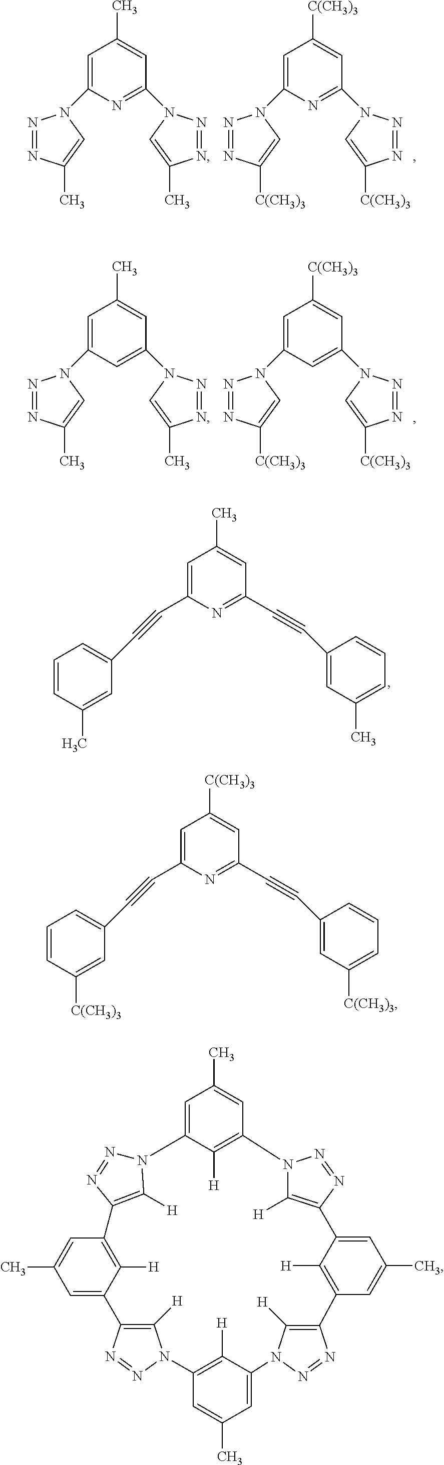

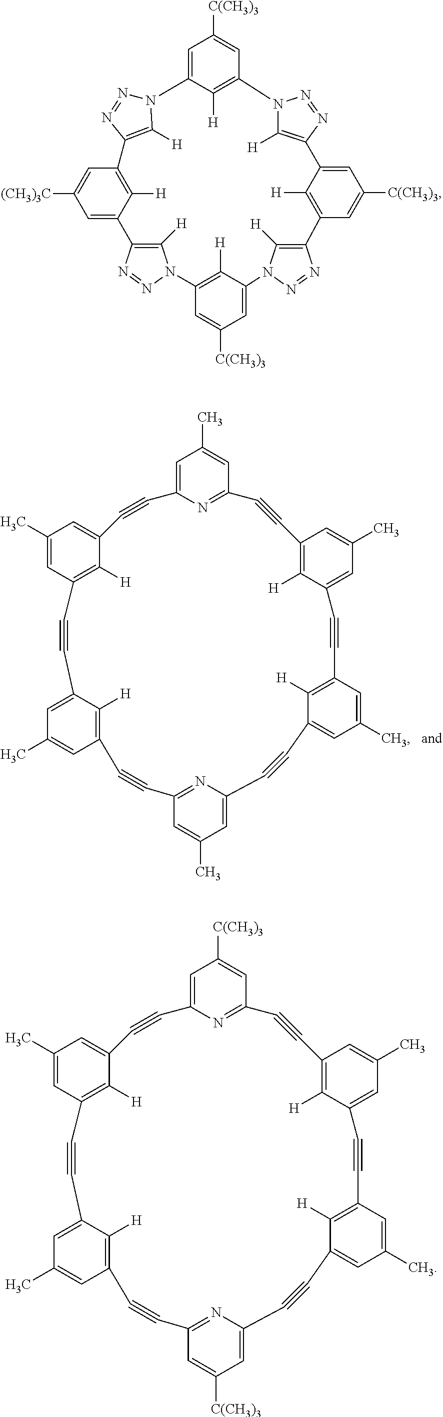 [SMILES: CC(C)(C)c1cc2cc(c1)-c1cn(nn1)-c1cc(cc(C(C)(C)C)c1)-n1cc(nn1)-c1cc(cc(C(C)(C)C)c1)-c1cn(nn1)-c1cc(cc(C(C)(C)C)c1)-n1cc-2nn1 ; Cc1cc2c#cc3cc(C)cc(c#cc4cc(C)cc(c#cc5cc(C)cc(c#cc6cc(C)cc(c#cc7cc(C)cc(c#cc(c1)c2)n7)c6)c5)n4)c3 ; Cc1cc2c#cc3cc(C)cc(c#cc4cc(C(C)(C)C)cc(c#cc5cc(C)cc(c#cc6cc(C)cc(c#cc7cc(C(C)(C)C)cc(c#cc(c1)c2)n7)c6)c5)n4)c3]

A dot light emitting diode, comprising:
an electrode layer,
an electrode modification layer, and
a charge transport layer arranged in layers, wherein the electrode layer, the electrode modification layer, and the charge transport layer are laminated, and the modification layer is located between the electrode layer and the charge transport layer, and wherein the material of the electrode modification layer is made of the composite material disclosed in the above.

Alternatively, a work function of the material in the electrode layer is higher than the work function of the material in the charge transport layer.

Alternatively, the electrode layer is a metal electrode layer.

Alternatively, a material of the charge transport layer is selected from one or more of ZnO, TiO₂, ZrO₂, HfO₂, SrTiO₃, BaTiO₃, MgTiO₃, Alq₃, Almq₃, DVPBi, TAZ, OXD, PBD, BND, PV, TFB, MoO₃, WO₃, NiO, V₂O₅, CuO, P-type gallium nitride, CrO₃, TPD, NPB, PVK, CBP, Spiro-TPD, and Spiro-NPB.

Alternatively, a material of the metal electrode layer is selected from one or more of Au, Ag, Al, Cu, and Pt.

Alternatively, the dot light emitting diode further comprises a light-emitting layer arranged with the electrode layer, the electrode modification layer, and the charge transport layer; the light-emitting layer is arranged on a side of the charge transport layer away from the electrode layer; and wherein a material of the light-emitting layer comprises quantum dots and surface ligands containing a sulfhydryl group connected on the surface of the quantum dots.

Alternatively, the surface ligands containing sulfhydryl groups are selected from one or more of thioglycolic acid, mercaptopropionic acid, mercaptobutyric acid, mercaptooleic acid, mercaptoglycerol, mercaptoethylamine, mercaptooleamine, and glutathione.

Alternatively, the quantum dots are selected from one or more of the group IV semiconductor nanocrystals, group II-V semiconductor nanocrystals, group II-VI semiconductor nanocrystals, group IV-VI semiconductor nanocrystals, and group III-V semiconductor nanocrystals.

A light-emitting diode preparation method, comprising:
providing a substrate; and
forming a stacked electrode layer, an electrode modification layer and a charge transport layer in sequence on the substrate; wherein the electrode modification layer is arranged between the electrode layer and the charge transport layer;
wherein a material of the electrode modification layer is made of the composite material disclosed in the above.

### Beneficial Effect

The composite material provided in this present disclosure uses heteromacrocyclic compound to bind the anion of the carbolong compound, to open the molecular distance of the carbolong compound, to create a charge transfer channel, to improve the charge transfer performance of the device, and to avoid affecting the charge transfer of the device based on the electrode layer and the electrode modification layer after the electrode modification layer is installed on the surface of the electrode layer. At the same time, the anion of the carbolong compound is adsorbed on the electrode layer, and the cation is located on the outside of the electrode, so that the carbolong compound forms a negative and cation spatial dipole arrangement between the electrode layer and the charge transport layer of the device, reducing the work function of the material of the electrode layer, and making the work function between the electrode layer and the charge transport layer of the device based on the electrode modification layer more matching. Thus, the service life of the device is increased. In addition, heteromacrocyclic compound can further reduce the work function of the electrode, optimize the energy level matching between the electrode and the adjacent charge transport layer, especially the electron transport layer, reduce the voltage drop and internal resistance of the device, reduce the opening voltage of the device, and thus improve the life of the device.

In the light-emitting diode provided in this present disclosure, an electrode modification layer is arranged between the electrode layer and the charge transfer layer, and a negative and cationic spatial dipole arrangement is formed between the electrode modification layer and the charge transfer layer through the carbolong compound in the electrode modification layer, so as to reduce the work function of the electrode layer, optimize the energy level matching between the electrode layer and the charge transfer layer, and improve the service life of the device. At the same time, the heteromacrocyclic compound in the electrode modification layer bind the anions of the carbolong compound, so that the molecular spacing between the carbolong compound molecules is widened, forming a channel that can be used for charge transfer, so as to avoid the charge transfer rate reduction of the device due to the addition of the electrode modification layer.

The light-emitting diode preparation method provided in this present disclosure is simple and has wide applicability.

### BRIEF DESCRIPTION OF FIGURES

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a flowchart of a method for preparing a light-emitting diode of the present disclosure.

FIG. 2 is a flowchart of a method for preparing an inverted light-emitting diode of the present disclosure.

FIG. 3 is a flowchart of a method for preparing a quantum dot light emitting diode according to Example 1 of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

The embodiments of the present disclosure provide a quantum dot light emitting diode device, a manufacturing method thereof and a display panel. Detailed descriptions are given below. It should be noted that the order in which the following embodiments are described is not intended to limit the preferred order of the embodiments.

Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

The first aspect, the present disclosure discloses a composite material, comprising:
a carbolong compound, comprising anions and cations; and
a heteromacrocyclic compound, selected from one of a substituted or unsubstituted heteroaromatic compound which has 6-20 annular atoms and is of a semi-ring structure, a substituted or unsubstituted heteroaromatic compound having 12-50 annular atoms, a dimer of a substituted or unsubstituted heteroaromatic compound having 12-50 annular atoms, and a trimer of a substituted or unsubstituted heteroaromatic compound having 12-50 annular atoms;
wherein the molar ratio of the carbolong compound to the heteromacrocyclic compound is 1:1-3.

The carbolong compound is selected from compound in carbolong chemistry. Carbolong chemistry is the chemistry in which a plane conjugated carbon chain chelates a transition metal through three or more carbon-metal σ bonds, including a series of aromatic skeletons formed by the combination of carbon chains and transition metals. The carbon chain is a pure carbon chain ligand composed of 7-12 carbon atoms.

In some embodiments, the general chemical formula of the carbolong compound is:

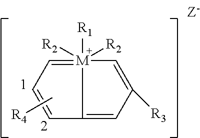

where in a general fomular I, R₁ and R₃ are independently selected from one or more of —H, halogen, —SCN, cyanogroup, alkyl group with 1-20 carbon atoms, alkoxy group, alkylthio group, ester group, amide group, amine group, carboxyl group, substituted amide group having 2-20 carbon atoms, cycloalkyl group having 3-20 carbon atoms, substituted or unsubstituted aryl group, and substituted or unsubstituted alkenyl group having 2-20 carbon atoms, substituted or unsubstituted alkynyl group having 2-20 carbon atoms, an aryl oxygen group having 6-20 carbon atoms, and an aryl sulfur group having 6-20 carbon atoms;
R₂ is independently selected from one of the —H, quaternary phosphine groups having 3-30 carbon atoms, and pyridinyl groups having 6-7 carbon atoms;
R₄ is selected from one or more of substituted or unsubstituted aryl groups, substituted or unsubstituted alkenyl groups having 2-20 carbon atoms, substituted or unsubstituted alkynyl groups having 2-20 carbon atoms,

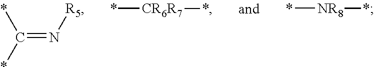

wherein, when the group represented by the R₄ contains two linking sites, the R₄ is ringed with two carbon atoms shown by 1 to 2 in formula I;
R₅, R₆, and R₇ are independently selected from one or more of —H, halogen, —SCN, cyanogroup, alkyl group having 1-20 carbon atoms, alkoxy group, alkylthio group, ester group, amide group, amine group, carboxyl group, substituted amide group having 2-20 carbon atoms, cycloalkyl group having 3-20 carbon atoms, substituted or unsubstituted aryl group, and substituted or unsubstituted aryl group having 2-20 carbon atoms One or more of alkenyl groups with carbon atoms, substituted or unsubstituted alkynyl groups having 2-20 carbon atoms, aryl oxygen groups having 6-20 carbon atoms, and aryl sulfur groups having 6-20 carbon atoms;
R₈ is selected from one or more of substituted or unsubstituted aryl groups, substituted or unsubstituted alkyl groups having 1-20 carbon atoms, and substituted or unsubstituted cycloalkyl groups having 3-20 carbon atoms;
R₁₅ is selected from one of substituted or unsubstituted alkyls, and substituted or unsubstituted ether groups;
M is selected from transition metal;
Z⁻ is an anion, which is specifically selected from one of BF⁻, OTf⁻, BF₄⁻, Cl⁻, Br⁻, F⁻, I⁻, CN⁻, and BrO₄⁻.

Specifically, BF⁻ refers to boron monofluoride ion, OTf⁻ refers to trifluoromethanesulfonate ion, BF₄⁻ refers to boron tetrafluoride ion, Cl⁻ refers to chloride ion, Br⁻ refers to bromine ion, F⁻ refers to fluorine ion, I⁻ refers to iodide ion, CN⁻ refers to cyanogen ion, and BrO₄⁻ refers to perbromate ion.

It should be noted that in the present disclosure, a single bond connected to a substituent run through the corresponding ring, indicating that the substituent may be connected to any position of the ring. For example,

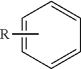

indicating that R is connected to any replaceable site of the benzene ring, where R represents a substituent.

In some embodiments, the quaternary phosphine groups having 3-30 carbon atoms is selected from one of three methyl phosphine, triethylphosphine, tripropylphosphine, triisopropylphosphine, tritert-butylphosphine, tricyclohexylphosphine, and triphenyl phosphine.

In some embodiments, the pyridinyl groups having 6-7 carbon atoms is selected from one of methyl pyridine, and ethyl pyridine.

In some embodiments, the halogen is selected from one of —Cl, —Br, —F, and —I.

In some embodiments, the alkyl group in R₁, R₃, R₅, R₆ and R₇ can be alkyl groups with 1-20 carbon atoms. R₁, R₃, R₅, R₆ and R₇ can be independently selected from one of methyl, ethyl, n-propyl, isopropyl, n-butyl, isobutyl, tert-butyl, n-amyl, isoamyl, neopentyl, para-amyl, tert-amyl, n-hexyl, isohexyl, n-heptyl, isoheptyl, n-octadecyl, and n-eicodecyl.

In some embodiments, the alkoxy group in R₁, R₃, R₅, R₆ and R₇ can be independently selected from one of methoxy, ethoxy, n-propoxy, isopropoxy, n-butoxy, isobutoxy, tert-butoxy, n-amyl, isoamyl, neopentyl, para-amyl, tert-amyl, n-hexyl, isohexyl, tert-hexyl, n-heptoxy, isoheptoxy, n-octyloxy, and neoctyloxy One of the alkoxy groups, such as paroctyloxy, tertiary octyloxy, n-dodecanoxy, n-hexadecanoxy, n-octadecanoxy, and n-eicosanoxy.

In some embodiments, the alkyl-sulfur group in R₁, R₃, R₅, R₆ and R₇ can be selected from one of methyl-sulfur, ethyl sulfur, n-propyl-sulfur, isopropyl-sulfur, n-butyl sulfur, isobutyl sulfur, sec-butyl sulfur, tert-butyl sulfur, n-amyl sulfur, isoamyl sulfur, neopentyl sulfur, para-amyl sulfur, tert-amyl sulfur, n-hexyl sulfur, isohexyl sulfur, neohexyl sulfur, sec-hexyl sulfur, tert-hexyl sulfur, n-heptyl sulfur, isoheptyl sulfur, n-heptyl sulfur, isoheptyl sulfur, n-heptyl sulfur, isoheptyl sulfur, n-butyl sulfur, isopropyl-sulfur, n-butyl sulfur, isobutyl sulfur, isobutyl sulfur, isobutyl sulfur, isobutyl sulfur, isobutyl sulfur, isobutyl sulfur, isobutyl sulfur, isobutyl sulfur, isobutyl sulfur, isobutyl sulfur, isobutyl sulfur, isobutyl sulfur, isobutyl sulfur, isobutyl sulfur, isobutyl sulfur, isobutyl sulfur. Any of several alkyl-sulfur groups, such as neoheptyl, sec-heptyl, tert-heptyl, n-octyl, iso-octyl, neooctyl, sec-octyl, tert-octyl, n-dodecane, n-cetane, n-octadecane, and n-eicosane.

In some embodiments, the ester group can be selected from one of

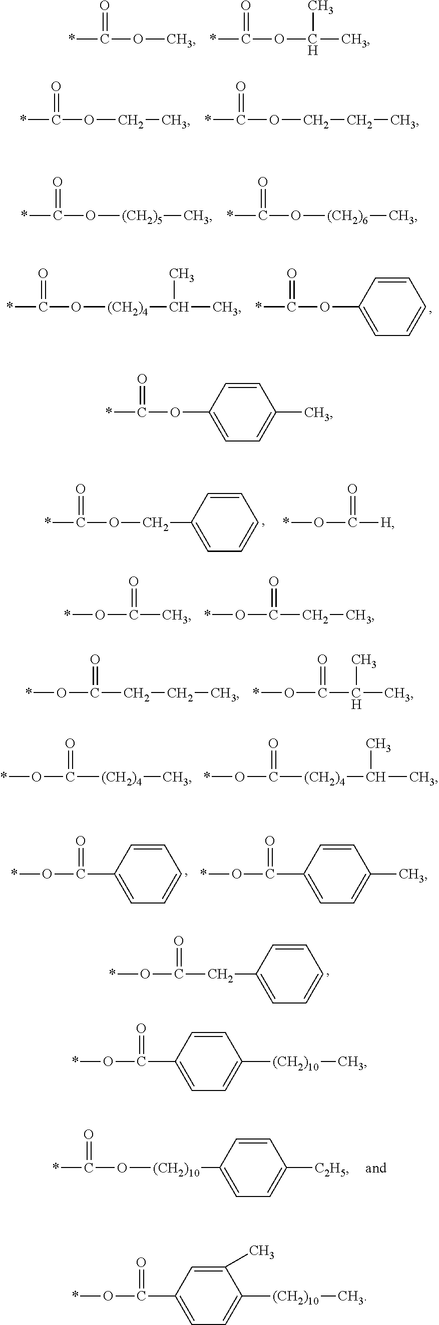

In some embodiments, the amide group can be selected from one of

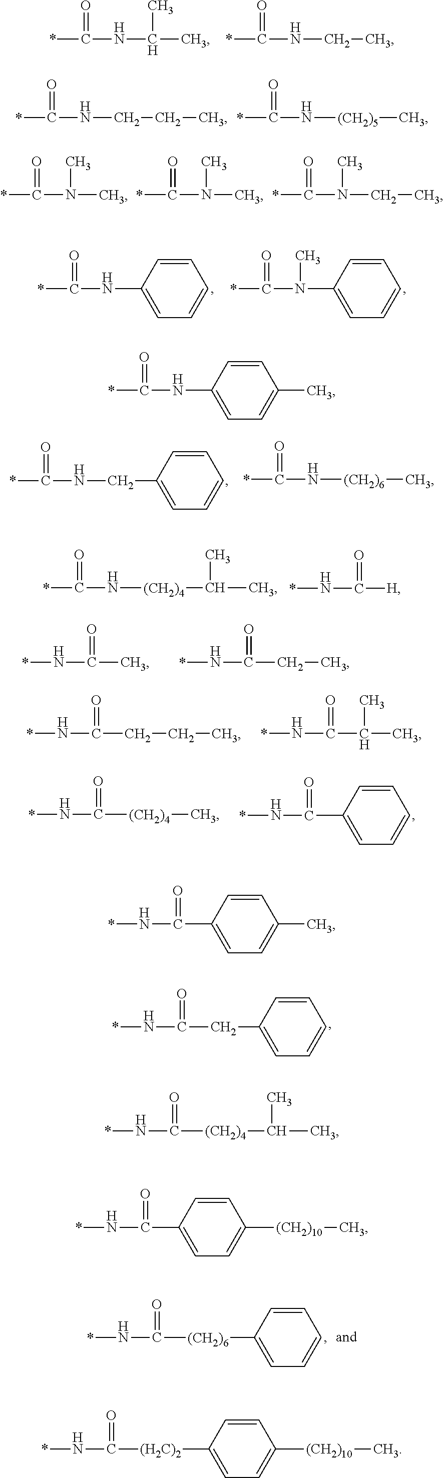

In some embodiments, the carboxyl group can be selected from one of

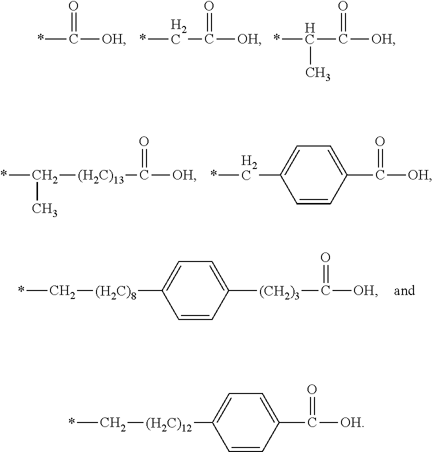

In some embodiments, the amine group can be selected from one of methylamine, ethylamine, propylamine, butylamine, pentamyl, hexylamine, heptyl, octylamine, dimethylamine, diethylamine, dipropylamine, dibutylamine, n-dodecylamine, n-hexadecylamine, n-octadecylamine, and or n-eicosamine.

In some embodiments, the substituted amide group having 2-20 carbon atoms can be selected from one of

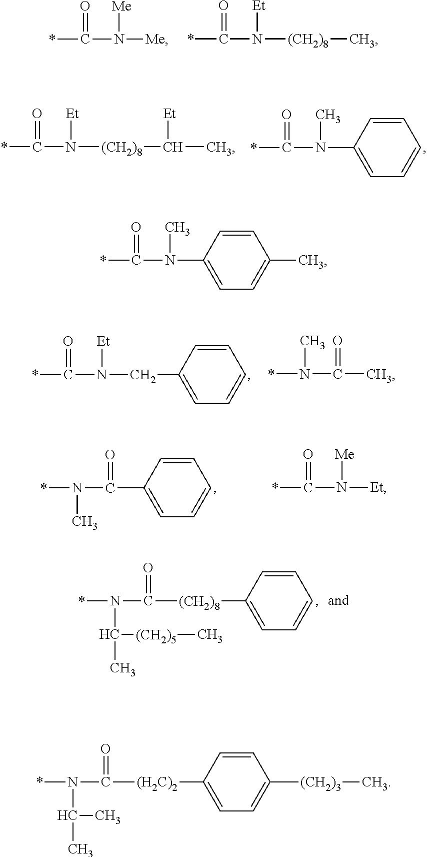

In some embodiments, the cycloalkyl group having 3-20 carbon atoms can be selected from one of cyclopropyl, cyclobutyl, cycloamyl, cyclohexyl, cycloheptyl, cyclooctyl, cyclododecyl, cyclohexadecyl, cyclooctadecyl, cycloeicosicyl, phenyl, naphthyl, anthracyl, phenanthyl, pyrene, thiophenyl, furan, pyridinyl, and pyrrole.

In some embodiments, the substituted or unsubstituted aryl group can be selected from one of

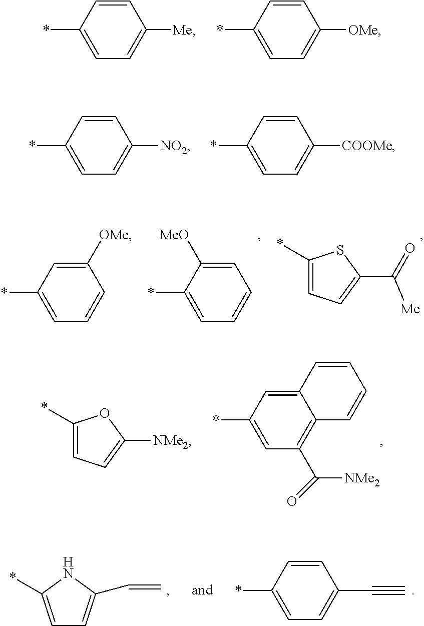

In some embodiments, the substituted or unsubstituted alkenyl group having 2-20 carbon atoms can be selected from one of

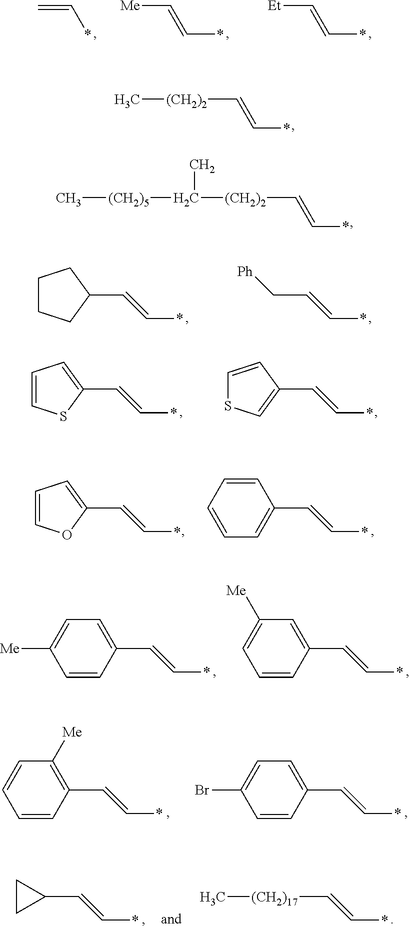

In some embodiments, the substituted or unsubstituted alkynyl group having 2-20 carbon atoms can be selected from one of

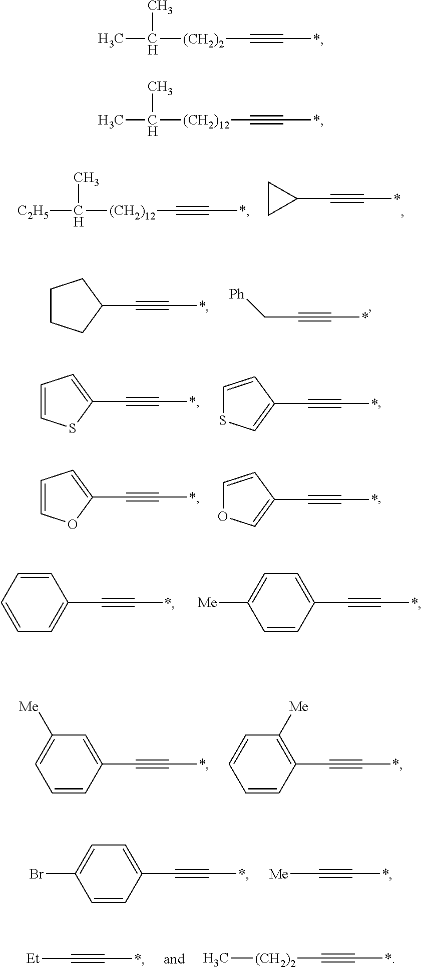

In some embodiments, the aryl oxygen group having 6-20 carbon atoms can be selected from one of phenoxy, naphthoxy, anthracyloxy, phenoxy, pyrene, Thiophenyl, furanoxy, pyridinoxy, pyrroloxy, p-toluloxy, m-toluloxy, o-toluloxy, p-nitrophenoxy, and p-methoxyphenoxy.

In some embodiments, the aryl sulfur group having 6-20 carbon atoms can be selected from one of phenyl-thiophenyl, naphthalene thiophenyl, anthracene thiophenyl, pyrene thiophenyl, furan thiophenyl, pyridine thiophenyl, p-toluene thiophenyl, m-toluene thiophenyl, o-toluene thiophenyl, p-nitrophenyl-thiophenyl, and p-methoxyphenyl-thiophenyl.

In some embodiments, the

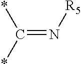

can be selected from one of

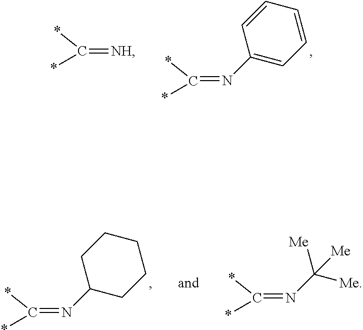

In some embodiments, the

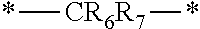

can be selected from one of

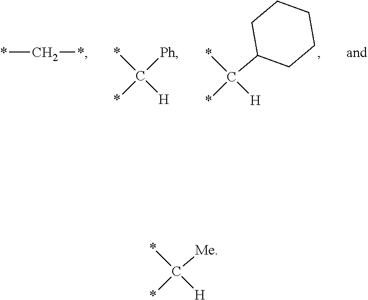

In some embodiments, the

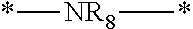

can be selected from one of

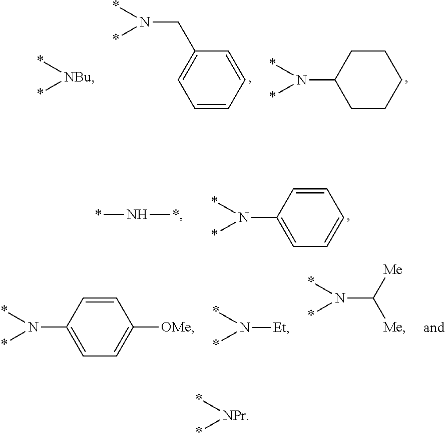

In some embodiments, R₁ and R₃ can be independently selected from one of —H, halogen, and —CO;

Each time R₂ appears, it is independently selected from one of the —H, and —PPh₃;

R₄ is selected from one of

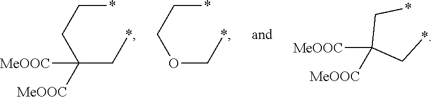

In some embodiments, the transition metal is selected from one of iridium, osmium, and rhodium.

In some embodiments, the heteromacrocyclic compound is m doubly symmetric compound, wherein m is an integer and m≥2.

It should be noted that m doubly symmetric compound should be understood as when the compound is rotated 360°/m about its axis (m=2,3,4,5,6 . . . ). The resulting compound is then completely overlapped with the original compound, where this axis is the m symmetry axis of this compound.

In some embodiments, the heteromacrocyclic compound include one or more heteroatoms selected from one of the nitrogen atoms, sulfur atoms, and oxygen atoms.

In some embodiments, the chemical formula of heteromacrocyclic compound has one of the chemical formulas shown in formula II, III, IV, and V:

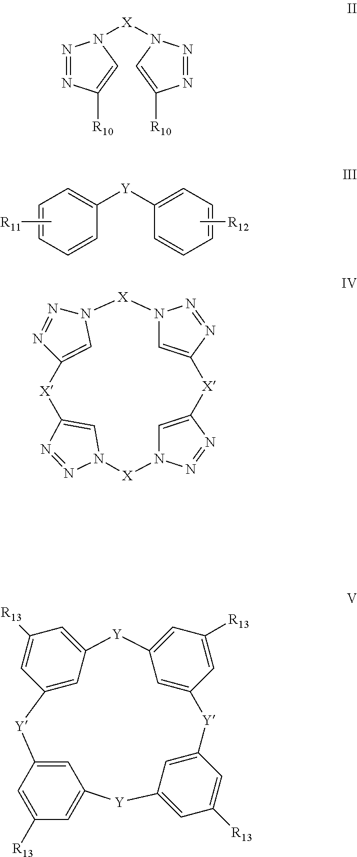

wherein the general fomular II to V, R₁₀ and R₁₃ are independently selected from one of —H, alkyl, alkoxy, and octyl-beta-d-thiopyranoside groups;
R₁₁ and R₁₂ are selected from one of —H, alkyl, alkoxy, and octyl-β-D-thiopyranoside groups; wherein R₁₁ and R₁₂ are the same group, and the connection of R₁₁ and R₁₂ makes Formula III symmetrical;
X and X′ are independently selected from one of substituted or unsubstituted aryl groups, and substituted or unsubstituted pyridine groups;
Y is selected from one of the substituted or unsubstituted pyridine group, and

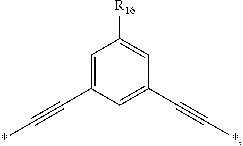

wherein R₁₆ is selected from one of —H, methoxy, and tert-butoxy groups;
Y′ is an alkyne group having two carbon atoms.

In some embodiments, the alkyl groups in R₁₀, R₁₁, R₁₂ and R₁₃ are independently selected from one of methyl groups, and tert-butyl groups;
the alkoxy groups in R₁₀, R₁₁, R₁₂ and R₁₃ are independently selected from one of the methoxy, and tert-butoxy groups.

In some embodiments, X and X′ are selected from one of

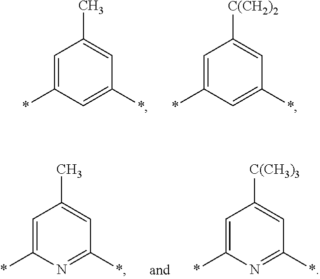

In some embodiments, Y is selected from one of

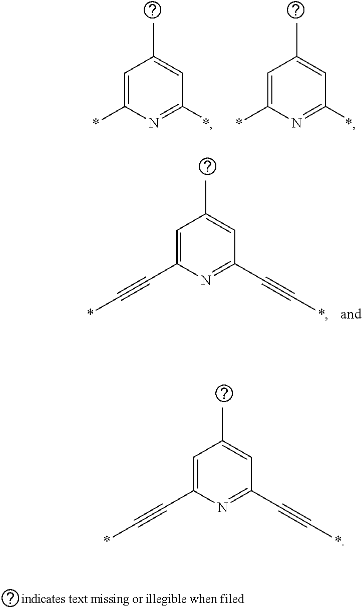

It should be noted that, in the present disclosure, the connection sites of all groups are one or both ends of the structural formula of the group expressed as “*” or “-”. Where, X, X ‘and Y are also groups, and both ends of X, X’ and Y are connected to aryl or heteroaryl groups in heteromacrocyclic compound, respectively.

In some embodiments, the carbolong compound is selected from one of

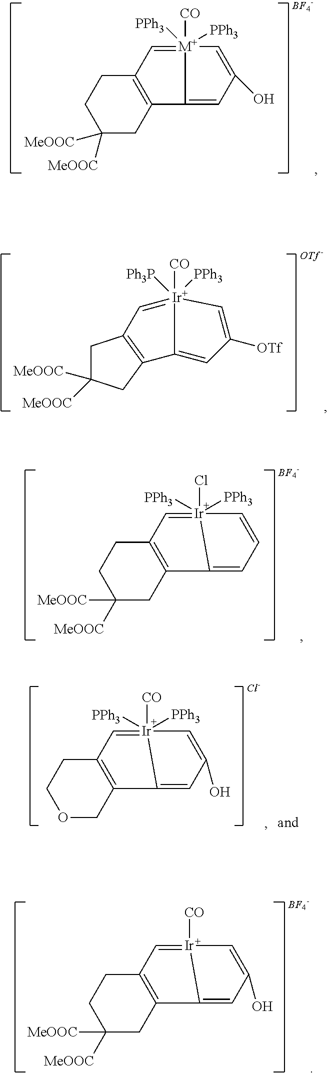

In some embodiments, the heteromacrocyclic compound is selected from one of

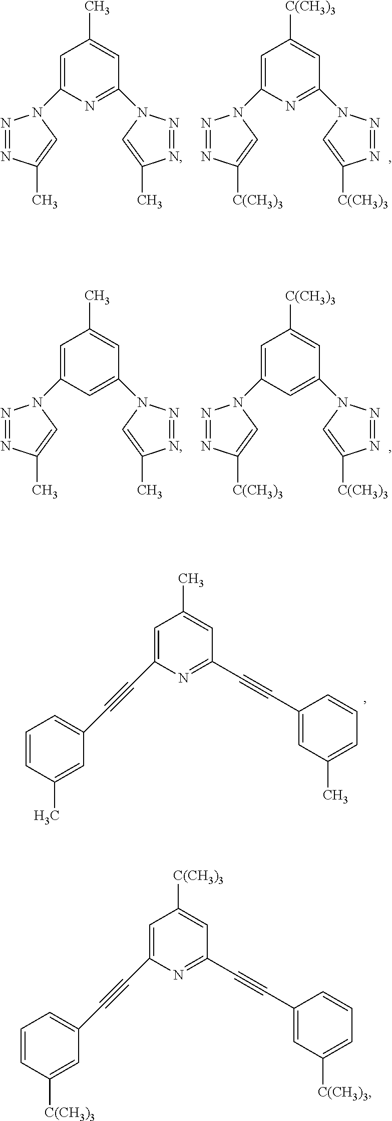

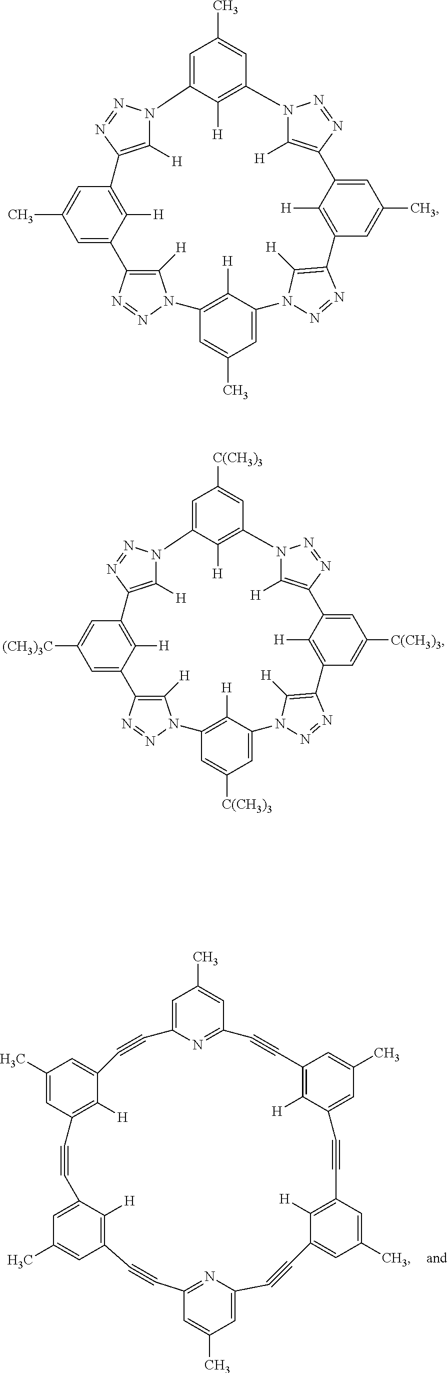 [SMILES: Cc1cc2cc(c1)-c1cn(nn1)-c1cc(C)cc(c1)-n1cc(nn1)-c1cc(C)cc(c1)-c1cn(nn1)-c1cc(C)cc(c1)-n1cc-2nn1 ; CC(C)(C)c1cc2cc(c1)-c1cn(nn1)-c1cc(cc(C(C)(C)C)c1)-n1cc(nn1)-c1cc(cc(C(C)(C)C)c1)-c1cn(nn1)-c1cc(cc(C(C)(C)C)c1)-n1cc-2nn1 ; Cc1cc2c#cc3cc(C)cc(c#cc4cc(C)cc(c#cc5cc(C)cc(c#cc6cc(C)cc(c#cc7cc(C)cc(c#cc(c1)c2)n7)c6)c5)n4)c3]

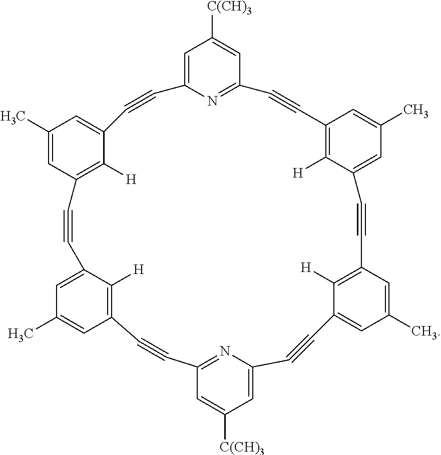

In some embodiments, the heteromacrocyclic compound can also be macrocyclic compounds whose basic structural unit is

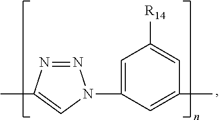

wherein n is an integer and n≥4.

R₁₄ is selected from one of —H, alkyl, alkoxy, and octyl-beta-d-thiopyranoside groups.

It should be noted that, in the present disclosure, heteromacrocyclic compound is selected from one of a group of polymers containing a macrocyclic structure, a group of compounds containing a semicyclic structure, and a group of compounds containing a macrocyclic structure. Among them, the macrocyclic structure is a ring structure formed by covalent bond between non-hydrogen atoms on heterocyclic unit and non-hydrogen atoms on benzene ring unit and alkyne unit. The semi-ring structure is a semi-ring structure formed by covalent bond between non-hydrogen atoms on heterocyclic unit and non-hydrogen atoms on benzene ring unit and alkyne unit. In the present disclosure, the atoms constituting a macrocyclic or semi-cyclic structure are referred to as ring atoms, and the number of ring atoms in the structure of each heterocyclic compound is calculated as the minimum number of non-hydrogen atoms required to constitute the macrocyclic or semi-cyclic structure of the heterocyclic compound, where non-hydrogen atoms are atoms other than hydrogen atoms. The semi-ring structure is formed of 6-20 ring atoms. The macrocyclic structure is formed of 12-50 ring atoms.

Taking

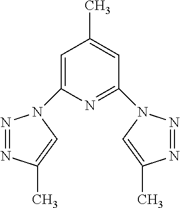 [SMILES: Cc1cc(-n2cc(C)nn2)nc(-n2cc(C)nn2)c1]

as an example, the ring atoms that make up the semi-ring structure of the heteromacrocyclic compound are labeled as follows:

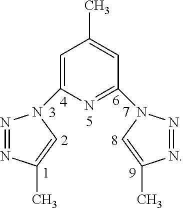 [SMILES: Cc1cc(-n2cc(C)nn2)nc(-n2cc(C)nn2)c1]

That is, in the heteromacrocyclic compound, the ring atoms that make up the semi-ring structure are the atoms shown in the labels 1-9, which specifically includes 3 heteroatoms (nitrogen atoms) and 6 carbon atoms. Taking the macrocyclic structure

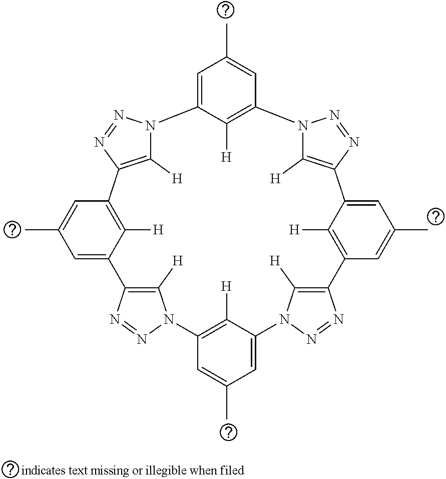

as an example, the ring atoms that make up the macrocyclic structure of the heteromacrocyclic compound are labeled as follows:

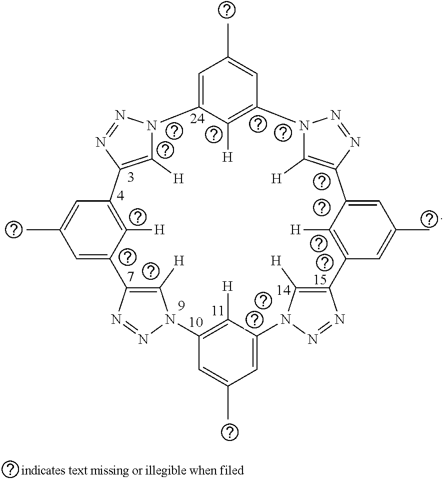

That is, in the heteromacrocyclic compound, the ring atoms that make up its macrocyclic structure are the atoms shown in labels 1-24, which specifically includes 4 heteroatoms (nitrogen atoms) and 20 carbon atoms.

The heteromacrocyclic compound provided in the present disclosure, contains an aromatic ring such as a heterocyclic ring and/or a benzene ring, and the aromatic ring such as a benzene ring and/or a heterocyclic ring contains a part of a carbon atom as a ring atom constituting the macrocyclic structure of the heterocyclic compound or a ring atom constituting the semi-cyclic structure of the macrocyclic compound, and the carbon atoms in the aromatic ring such as a benzene ring and/or a heterocyclic ring are both as ring atoms. This carbon atom has hydrogen attached to it. In other words, the heteromacrocyclic compound contain carbon that is used both to form a benzene ring or heterocyclic ring, and also as a ring atom with a macrocyclic structure or a semi-cyclic structure, and the carbon is attached to hydrogen.

It should be noted that due to the strong polarization of both benzene ring and heterocyclic ring, the C—H bond is polarized, providing a strong coulomb interaction, binding the anion inserted into the heteromacrocyclic compound and the carbolong compound, and stretching the molecular distance between the carbolong compound, so that the carbolong compound has a certain molecular distance When the composite material is arranged between the charge transport layer and the metal-based electrode, the anions in the carbonic compound are adsorbed on the surface of the electrode, and the cations are distributed on the outside of the anions, so that the carbolong compound on the surface of the electrode stably forms the spatial dipole arrangement of the negative-cation layer, thus reducing the work function of the metal forming the electrode. The voltage drop and internal resistance of the device based on the electrode and charge transport layer are reduced, and the current density is increased. At the same time, because the anion of the carbonic compound is inserted into the macrocyclic or semi-ring of the heteromacrocyclic compound, the molecular spacing of the carbolong compound is opened, and the channel that can be used for charge transport is formed, and the rate of charge transmission between the electrode and the charge transport layer is increased. In addition, heteromacrocyclic compound can further reduce the work function of the metal electrode, further optimize the energy level matching between the metal electrode and the adjacent charge transport layer, especially the electron transport layer, reduce the voltage drop and internal resistance of the device, reduce the opening voltage of the device, and improve the life of the device.

For a better understanding of the present disclosure, a preparation method of carbolong compound is also provided, including:

Providing a solution of compound A and a solution of compound B, mixing the solution of compound A and the solution of compound B, reacting for 10-30 min, adding compound C after concentration, separating, and drying to obtain the carbolong compound.

The reaction route is as follows:

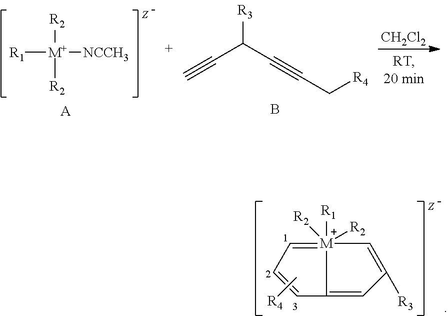

The solution of compound A is dichloromethane solution of compound A, and its concentration is 0.02˜0.05 mol/L. The solution of compound B is dichloromethane solution of compound B, and its concentration is 0.05˜0.15 mol/L.

Compound C is used to reduce the solubility of the product in the reaction system, so that the carbolong compound is precipitated. Compound C can be ether, and the amount of its addition can be adjusted according to the volume of the reaction system.

For a better understanding of the present disclosure, a preparation method of heteromacrocyclic compound based on 1,2,3-triazole is also provided, including:

Providing a solution of compound D and a solution of compound E, mixing the solution of compound D and the solution of compound E, reacting for 10-20 h, and separating to obtain the heteromacrocyclic compound.

The reaction route is as follows:

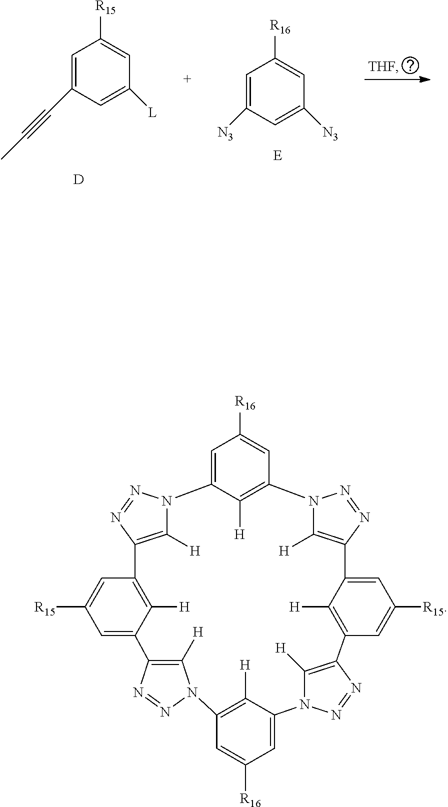

L stands for halogen, preferably I.

The solution of compound D is the ethanol solution of compound D, and its concentration is 0.005˜0.01 mol/L. The solution of compound E is THE solution of compound E, and its concentration is 0.05˜0.1 mol/L. The solution of compound D was obtained by adding the compound D to ethanol and stirring at 50-80° C. for 30-90 min.

After separating, it can also be washed by dichloromethane, and then recrystallized by a mixed solution of trichloromethane and ether to obtain the heteromacrocyclic compound with higher purity.

In order to better understand the present disclosure, an electrode modification layer solution is also provided, so that the electrode modification layer can be deposited by the solution, which is convenient for the preparation of the electrode modification layer. At the same time, the carbolong compound and the heteromacrocyclic compound form anions of carbolong compound into the stable state of heteromacrocyclic compound in solution, which is conducive to the formation of a negative and cationic dipole arrangement between the electrode layer and the functional layer of the device after the formation of the electrode modification layer, and the heteromacrocyclic compound bind the anions of the carbolong compound. This creates a channel for charge transport.

The electrode modification layer solution includes solute and solvent. Among them, the solute includes carbolong compound and heteromacrocyclic compound. And the molar ratio of carbolong compound to heteromacrocyclic compound is 1:1˜ 3.

It should be noted that the carbolong compound is the carbolong compound of the above, and the heteromacrocyclic compound is the heteromacrocyclic compound of the above, so it will not be repeated here.

It should be noted that the molar ratio of carbolong compound and heteromacrocyclic compound is 1:1˜3, which should be understood as the ratio of the molar content of carbolong compound in solution to the molar content of heteromacrocyclic compound in solution is 1:1˜3. Further, the molar ratio of carbolong compound and heteromacrocyclic compound in solution is 1:1.8˜2.5. The molar ratio of carbolong compound and heteromacrocyclic compound in solution should not be too high or too low. Excessive molar ratio will lead to excessive carbolong compound in the solution, which will affect the creation of charge transport channels, and then affect the performance of the device based on the electrode modification layer. Too low molar ratio will lead to insufficient carbolong compound in the solution, resulting in the effect of electrode modification layer to reduce the electrode work function is not obvious.

In some embodiments, the concentration of solute in solvent is 10˜15 mg/mL. That is, the sum of the concentration of carbolong compound in the solvent and the concentration of heteromacrocyclic compound in the solvent is 10˜15 mg/mL. The concentration of carbolong compound and heteromacrocyclic compound in the solvent should not be too high or too low. Too high a concentration will lead to a decrease in the film formation of the solution and affect the performance of the device based on the electrode modification layer. Too low concentration will cause the material content in the electrode modification layer to decrease, resulting in the effect of the electrode modification layer to reduce the electrode work function is not obvious.

In some embodiments, the solvent is selected from one or more of C1˜C5 straight chain alcohols, C1˜C5 branched chain alcohols, chlorobenzene, and dimethyl sulfoxide. These solvents can make the resulting solution good film forming property.

In order to better understand this present disclosure, a preparation method of electrode modification layer solution is also provided, including: Mixing the carbolong compound and the heteromacrocyclic compound at a certain temperature, cooling to room temperature, and separating to ensure that anions in carbolong compound in solution are inserted into heteromacrocyclic compound. Thereby ensuring the molecular spacing between carbolong compounds, creating a charge transmission channel and improving the performance of light-emitting diodes based on electrode modification layers.

The preparation method of the electrode modification layer solution including:
providing carbolong compound, heteromacrocyclic compound and solvent;
mixing the carbolong compound, the heteromacrocyclic compound and the solvent at 80-100° C. for 0.5-2 h, cooling to room temperature, and separating to obtain solution;
wherein, the molar ratio of the carbolong compound and the heteromacrocyclic compound in the solution is 1:1˜3.

The carbolong compound and the heteromacrocyclic compound were mixed with the solvent at 80˜100° C., so that the carbolong compound, the heteromacrocyclic compound were dissolved in the solvent. Due to the strong polar C—H bond of heteromacrocyclic compound has a strong affinity for the anions in the carbolong compound, the anions in the carbolong compound are inserted into the macrocyclic structure or semi-cyclic structure of the heteromacrocyclic compound, and the anions in the carbolong compound are inserted into the heteromacrocyclic compound, and the cations in the carbolong compound are located in the outer structure.

The solubility of the carbolong compound and the heteromacrocyclic compound in the solvent was increased by mixing the carbolong compound and the heteromacrocyclic compound in the solvent at 80˜100° C. After mixing is completed, the heteromacrocyclic compound without anion insertion is precipitated due to cooling, and the carbolong compound without anion insertion into the heteromacrocyclic compound is also precipitated, and a solution is separated. It can ensure that the anion in the carblong compound in the solution is inserted into the heteromacrocyclic compound, and then ensure the molecular spacing between the carbolong compound, create a charge transport channel, and improve the performance of the LED based on the electrode modification layer.

In the second aspect, the present present disclosure also discloses a light-emitting diode, including:
an electrode layer;
an electrode modification layer; and
a charge transport layer arranged in layers, wherein the electrode layer, the electrode modification layer, and the charge transport layer are laminated, and the modification layer is located between the electrode layer and the charge transport layer; and wherein the material of the electrode modification layer is made of the composite material disclosed in the first aspect.

In some embodiments, a work function of the material in the electrode layer is higher than the work function of the material in the charge transport layer. When the electrode modification layer is located between the metal electrode layer and the charge transport layer, the anion of the carbolong compound in the electrode modification layer is inserted into the heteromacrocyclic compound and adsorbed on the surface of the metal electrode layer, which reduces the work function of the metal electrode layer, optimizes the energy level matching between the metal electrode layer and the charge transport layer, reduces the potential barrier, and improves the service life of the light-emitting diode. At the same time, the heteromacrocyclic compound in the electrode modification layer bind the anion of the carbolong compound, and open the molecular distance of the carbolong compound, so that several charge transfer channels are formed in the electrode modification layer, and the charge generated by the metal electrode layer is quickly transferred through the charge transfer channel, so as to optimize the performance of the light-emitting diode.

In some embodiments, the electrode layer is a metal electrode layer.

It should be noted that the metal electrode layer should be understood as the electrode layer prepared by metal materials, which can be a cathode or an anode. Correspondingly, the charge transport layer is a layer structure used for charge transport, which can be an electron transport layer, an electron injection layer, or a hole transport layer or a hole injection layer. When the metal electrode layer is the cathode, the charge transport layer is the electron transport layer or the electron injection layer, the cathode, the electrode modification layer, the electron transport layer/electron injection layer is stacked in sequence, and the work function of the cathode material is higher than that of the electron transport layer/electron injection layer. When the metal electrode layer is the anode, the charge transport layer is the hole transport layer or the hole injection layer. The anode, the electrode modification layer, and the hole transport layer/hole injection layer are set in sequence. The work function of the anode material is higher than the work function of the material in the hole transport layer/hole injection layer. The slash (/) indicates or.

When the charge transport layer is the electron injection layer, the cathode, the electrode modification layer, the electron injection layer and the electron transport layer of the light-emitting diode are stacked in sequence, and the work function of the cathode material, the material of the electron injection layer and the material of the electron transport layer decreases in sequence. Similarly, when the charge transport layer is the hole injection layer, the anode, the electrode modification layer, the hole injection layer and the hole transport layer are stacked in sequence, and the work function of the anode material, the material of the hole injection layer and the material of the hole transport layer is successively reduced.

It should be noted that the light-emitting diode provided in this present disclosure can be inorganic light-emitting diodes, organic light-emitting diodes, polymer light-emitting diodes, and quantum dot light-emitting diodes. The preparation method of the composite material, electrode modification layer solution and electrode modification layer solution provided in the present disclosure is also applicable to other photoelectric devices containing metal electrode layer and charge transport layer.

Since the cathode of the existing light-emitting diode is often made of metal material, the electrode modification layer is more suitable for setting between the electron transport layer and the cathode, especially between the cathode and the electron transport layer of the quantum dot light-emitting diodes. At present, metal electrode layer is commonly used in the cathode of QLED. In order to improve the stability of metal electrode layer, Ag and Au are often used as metal electrode layer. A material of the electron transport layer of quantum dot light-emitting diodes is usually metal oxide nanoparticles, such as zinc oxide nanoparticles. Therefore, the work function of the electron transport layer is lower than that of the metal electrode layer, which leads to a short service life of the QLED, which is a common shortcoming of the quantum dot light-emitting diodes. In the present disclosure, by setting an electrode modification layer between the electron transport layer and the metal electrode layer of the quantum dot light-emitting diodes, the material work function of the metal electrode layer can be significantly reduced without significantly reducing the electron transport efficiency, and the energy level matching between the metal electrode layer and the electron transport layer can be optimized to improve the service life of the quantum dot light-emitting diodes. It will play a positive role in promoting the commercialization of the quantum dot light-emitting diodes.

In some embodiments, the LED provided in this present disclosure also includes other layer structures, such as an electronic barrier layer arranged between the electron transport layer and the light-emitting layer.

It should be noted that the charge transport layer in the present disclosure may be an electron transport layer or a hole transport layer.

In some embodiments, the materials of the charge transport layer is selected from one or more of ZnO, TiO₂, ZrO₂, HfO₂, SrTiO₃, BaTiO₃, MgTiO₃, Alq₃, Almq₃, DVPBi, TAZ, OXD, PBD, BND, PV, TFB, MoO₃, WO₃, NiO, V₂O₅, CuO, P-type gallium nitride, CrO₃, TPD, NPB, PVK, CBP, Spiro-TPD, and Spiro-NPB.

When the electrode layer is the cathode, the charge transport layer is the electron transport layer. The electron transport layer materials can be selected from one or more of ZnO, TiO₂, ZrO₂, HfO₂, SrTiO₃, BaTiO₃, MgTiO₃, Alq₃, Almq₃, DVPBi, TAZ, OXD, PBD, BND, PV. When the electrode layer is the anode, the charge transport layer is the hole transport layer. The materials of the hole transport layer can be selected from one or more of TFB, MoO₃, WO₃, NiO, V₂O₅, CuO, P-type gallium nitride, CrO₃, TPD, NPB, PVK, CBP, Spiro-TPD, Spiro-NPB, and other hole transport layer materials.

In some embodiments, A material of the metal electrode layer is selected from one or more of Au, Ag, Al, Cu, and Pt. When the cathode of the LED is a metal electrode layer, the anode material can choose indium tin oxide (ITO), indium zinc oxide (IZO), and other conventional anode materials.

In the present disclosure, when the electrode layer is the cathode, the light-emitting diode provided in the present disclosure also includes a hole injection layer arranged between the anode and the hole transport layer. The material of the hole injection layer can be selected from one or more of PEDOT:PSS, CuPc (polyester carbonate), TiOPc, m-MTDATA, etc. 2-TNATA, MoO₃, and other cavity injection layer materials.

In some embodiments, the light-emitting diode further includes a light-emitting layer arranged with the electrode layer, the electrode modification layer, and the charge transport layer. The light-emitting layer is arranged on a side of the charge transport layer away from the electrode layer. The material of the light-emitting layer can choose one of organic luminescent materials, inorganic luminescent materials, and quantum dot luminescent materials. Among them, organic luminescent materials can be selected from oe or more of 4-(ii) acrylic methyl-2-butyl-6-(1,1,7,7-tetramethyl long los organism-9-vinyl)-4 h-pyran (DCJTB), 9,10-2(beta naphthyl) anthracene (ADN), 4,4′-double (9-ethyl-3-vinyl carbazole)-1,1′-biphenyl (BCzVBi), 8-hydroxyquinoline aluminium, polyp-styrene, polythiophene, polyaniline, polycarbazole, etc. Inorganic luminous materials can be selected from oe or more of ZnS:Mn, ZnS:Tb, ZnS:Tb/heterocyclic compound S, SiO₂:Ge, SiO₂:Er, SrS:Ce, CaGa₂S₄:Ce, SrGa₂S₄:Ce, SrS:Cu, GaN, ZnS:Tm, Zn₂SiO₂:Ca, etc. In which. “:” indicates doping; “/” indicates the encapsulation.

The quantum dot luminescent materials include quantum dots and surface ligands containing a sulfhydryl group connected on the surface of the quantum dots.

After coordinating the surface ligands containing sulfhydryl groups with the surface atoms of quantum dots, the modified sulfhydryl groups will be connected on the surface of quantum dots to improve the surface defect problem of quantum dots, and thus improve the stability of quantum dots. Preferably, when a diamine compound is added to the quantum dot synthesis process, the positively charged amino group at one end of the molecular chain of the diamine compound can generate electrostatic force with the negatively charged sulfhydryl group on the surface of the quantum dot to achieve electrostatic self-assembly. This is conducive to improving the film forming quality of quantum dots, further reducing the surface defects of the film layer interface, improving the performance and stability of quantum dots, and then improving the performance and stability of the quantum dot light-emitting diodes.

In some embodiments, the surface ligands containing sulfhydryl groups are selected from one or more of thioglycolic acid, mercaptopropionic acid, mercaptobutyric acid, mercaptooleic acid, mercaptoglycerol, mercaptoethylamine, mercaptooleamine, and glutathione.

In some embodiments, the quantum dots are selected from one or more of the group IV semiconductor nanocrystals, group II-V semiconductor nanocrystals, group II-VI semiconductor nanocrystals, group IV-VI semiconductor nanocrystals, and group III-V semiconductor nanocrystals, which may be selected specifically from: Silicon quantum dots, germanium quantum dots, cadmium sulfide quantum dots, cadmium selenide quantum dots, cadmium telluride quantum dots, zinc selenide quantum dots, lead sulfide quantum dots, lead selenide quantum dots, indium phosphide quantum dots, indium arsenide quantum dots, gallium nitride quantum dots and other quantum dots.

It should be noted that the light-emitting diodes can be an upright light-emitting diode or an inverted light-emitting diode. When the light-emitting diode is the upright light-emitting diodes, the upright light-emitting diodes comprises an anode, a hole transport layer, a light-emitting layer, an electron transport layer and a cathode arranged in layers, and the anode is arranged on the substrate. When the light-emitting diodes is the inverted light-emitting diodes, the inverted light-emitting diodes includes a laminated cathode, an electron transport layer, a light emitting layer, a hole transport layer and an anode, and the cathode is arranged on the substrate.

In the third aspect, the present disclosure also discloses a light-emitting diode preparation method, including:
providing a substrate;
forming a stacked electrode layer, an electrode modification layer and a charge transport layer in sequence on the substrate; wherein the electrode modification layer is arranged between the electrode layer and the charge transport layer;
wherein a material of the electrode modification layer is made of the composite material disclosed in the first aspect.

It should be noted that the forming a stacked electrode layer, an electrode modification layer and a charge transport layer on a substrate does not limit the formation sequence of the electrode layer, the electrode modification layer and the charge transport layer. It can be understood that the electrode layer, the electrode modification layer and the charge transport layer are successively formed on the substrate. It can also be understood as: the charge transport layer, the electrode modification layer and the metal electrode layer are formed on the substrate in turn.

Wherein, the substrate can be rigid substrate or flexible substrate. The rigid substrate can be selected from one or more of glass, and metal foil. The flexible substrate is selected from one or more of polyethylene terephthalate (PET), polyethylene terephthalate (PEN), polyether ether ketone (PEEK), polystyrene (PS), polyether sulfone (PES), polycarbonate (PC), polyaryl ester (PAT), polyaryl ester (PAR), polyimide (PI), polyvinyl chloride (PV), polyethylene (P) E), and polyethylene pyrrolidone (PVP).

In some embodiments, the electrode layer, the electrode modification layer, the charge transport layer, and the luminescent layer are obtained by deposition of a solution containing the corresponding material, including but not limited to one of the spinning coating, printing, scraping coating, dip and pull method, soaking method, spraying method, roll coating method, casting method, slit coating method, and strip coating method.

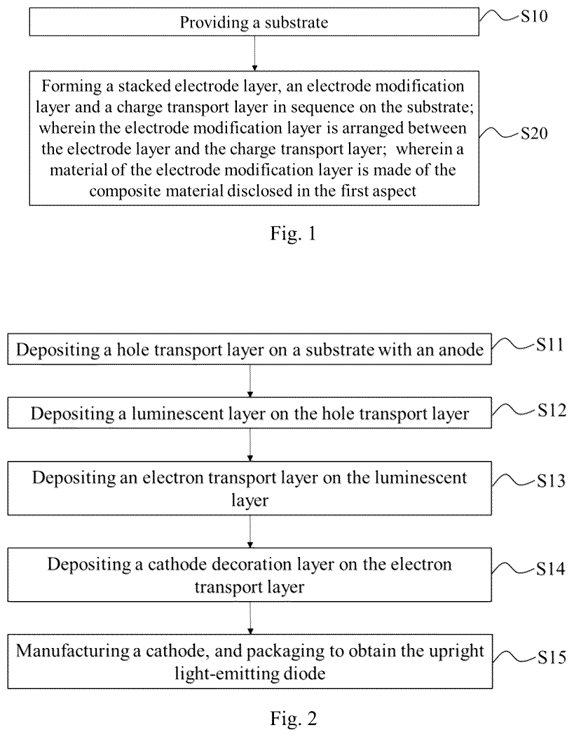

In some embodiments, referring to FIG. 1, a method for preparing an upright light-emitting diode, including:
S11, depositing a hole transport layer on a substrate with an anode;
S12, depositing a luminescent layer on the hole transport layer;
S13, depositing an electron transport layer on the luminescent layer;
S14, depositing a cathode decoration layer on the electron transport layer;
S15, manufacturing a cathode, and packaging to obtain the upright light-emitting diode.

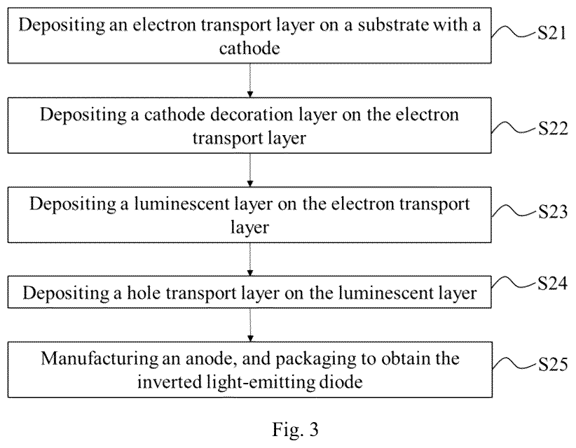

In some embodiments, referring to FIG. 2 the method for preparing an inverted light-emitting diode, including:
S21, depositing an electron transport layer on a substrate with a cathode;
S22, depositing a cathode decoration layer on the electron transport layer;
S23, depositing a luminescent layer on the electron transport layer;
S24, depositing a hole transport layer on the luminescent layer;
S25, manufacturing an anode, and packaging to obtain the inverted light-emitting diode.

In order to better understand the solutions, specific Examples 1-5 and Comparative Examples 1-5 are provided herein to further illustrate the solutions in detail.

### Example 1

### Preparation of a Carbolong Compound:

Adding compound A (300 mg, 0.34 mmol) to dichloromethane solution (15 mL) to obtain a yellow solution, and then slowly adding compound B (108 mg, 0.41 mmol) to dichloromethane solution (5 mL). Stirring at room temperature for 20 min to obtain a red solution. Evaporating the solution to a volume of about 5 mL under vacuum, then adding ether (50 mL) to generate red precipitate, collecting it with ether and vacuum drying to obtain red solid carbolong compound L1.

The specific reaction route is as follows:

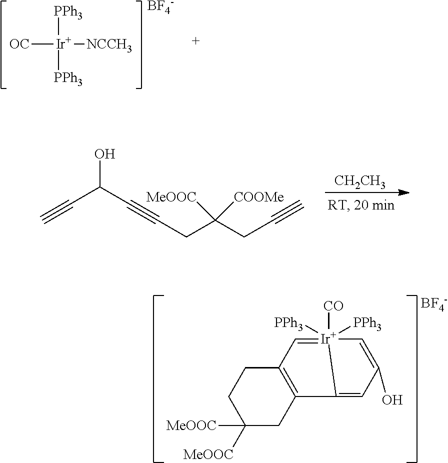

### Preparation of a Heteromacrocyclic Compound

mixing 6 mmol of compound D and 800 mL of ethanol at 60° C. for 1 hour, cooling to room temperature, adding 60 mmol of compound E and 800 mL of THF to mix for 12 hours, and obtaining coarse solid crystals. Washing and filtering the coarse solid crystals with dichloromethane, collecting the filtrate and drying it under vacuum to obtain the crude product. Mixing the crude product, chloroform and diethyl ether, and recrystallizing to obtain 9 g of pale yellow solid as heteromacrocyclic compound Q1.

The specific reaction route is as follows:

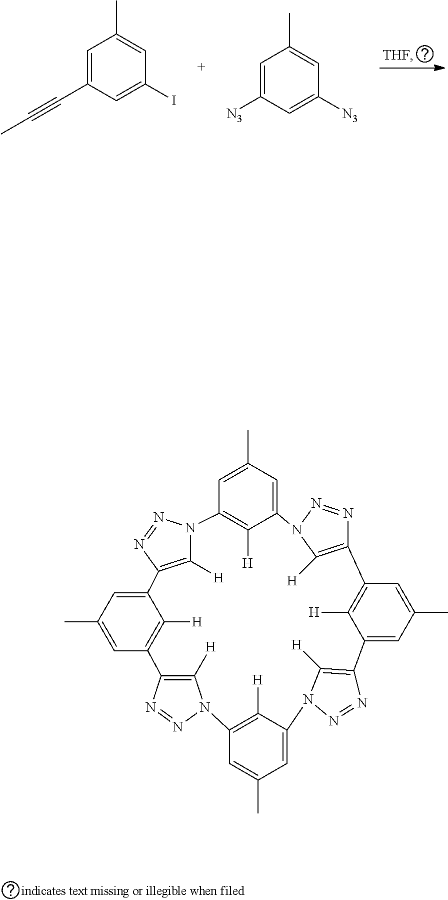

### Preparation of an Electrode Modification Layer Solution

adding the carbolong compound L1 and the heteromacrocyclic compound Q1 prepared above into ethanol according to the molar ratio of 1:2, stirring at 100° C. for 1 h, cooling to room temperature, and filtering the precipitate to obtain a clear filtrate, which is the electrode modification layer solution.

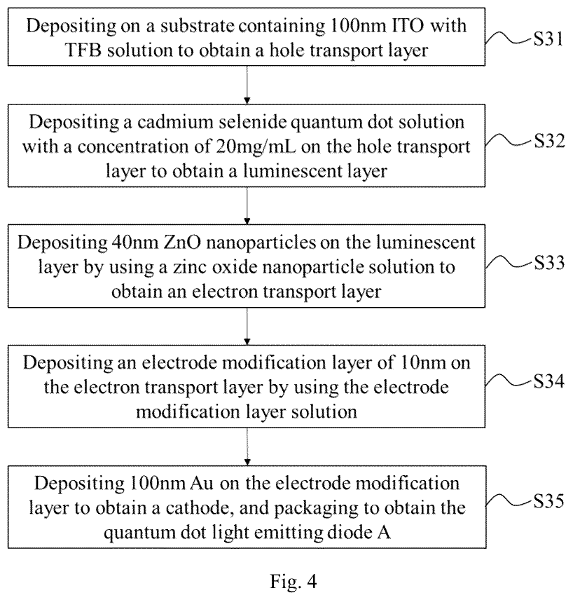

Referring to FIG. 3, using the electrode modification layer solution obtained above as the solution for depositing the electrode modification layer, a quantum dot light-emitting diode based on the electrode modification layer is prepared. The specific preparation steps are as follows:
S31, depositing on a substrate containing 100 nm ITO with TFB solution to obtain a hole transport layer;
S32, depositing a cadmium selenide quantum dot solution with a concentration of 20 mg/mL on the hole transport layer to obtain a luminescent layer;
S33, depositing 40 nm ZnO nanoparticles on the luminescent layer by using a zinc oxide nanoparticle solution to obtain an electron transport layer;
S34, depositing an electrode modification layer of 10 nm on the electron transport layer by using the electrode modification layer solution;
S35, depositing 100 nm Au on the electrode modification layer to obtain a cathode, and packaging to obtain the quantum dot light emitting diode A.

### Example 2

Compared with Example 1, in this example, 100 nm Al is deposited on the electrode modification layer as the cathode, and the other steps are the same as in Example 1 to obtain a quantum dot light-emitting diode B.

### Example 3

Compared with Example 1, in this example, the electrode modification layer solution is prepared by the following methods: adding the carbolong compound L1 and the heteromacrocyclic compound Q1 prepared above into ethanol according to the molar ratio of 1:3, stirring at 100° C. for 1 h, cooling to room temperature, and filtering the precipitate to obtain a clear filtrate, which is the electrode modification layer solution.

Taking the electrode modification layer solution obtained above as the solution for depositing the electrode modification layer, quantum dot light-emitting diode C was prepared by using the same light-emitting diode preparation method as that of Example 1.

### Example 4

Compared with Example 1, in this example, S321 is also arranged between S32 and S33, using PMMA solution, 2 nm was deposited on the quantum dot luminescent layer to obtain the electron blocking layer; and depositing an electrode modification layer solution on the electron transport layer to obtain an electrode modification layer, and the other steps are the same as in Example 1 to obtain a quantum dot light emitting diode D.

### Example 5

Compared with Example 1, in this example, the heteromacrocyclic compound is prepared by the following methods:

mixing 6 mmol of compound D and 800 mL of ethanol at 60° C. for 1 hour, cooling to room temperature, adding 60 mmol of compound E and 800 mL of THF to mix for 4 hours, and obtaining coarse solid crystals. Washing and filtering the coarse solid crystals with dichloromethane, collecting the filtrate and drying it under vacuum to obtain the crude product. Mixing the crude product, chloroform and diethyl ether, and recrystallizing to obtain 6 g of pale yellow solid as heteromacrocyclic compound Q1.

The specific reaction route is as follows:

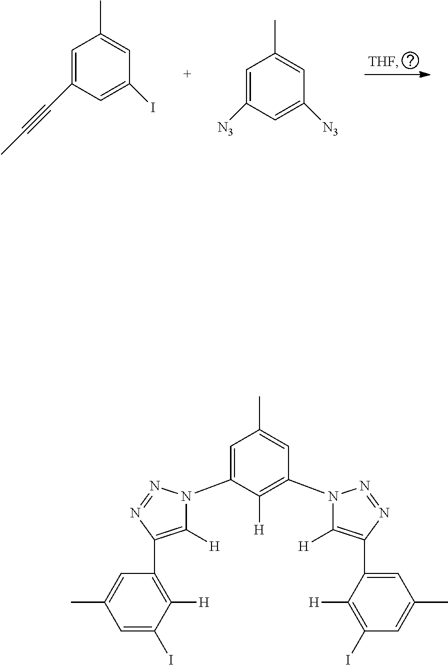

The electrode modification layer solution is prepared by using the carbolong compound L1 and heteromacrocyclic compound Q2, which are the same as Example 1, in accordance with the same steps as Example 1, and the electrode modification layer solution is used as the solution for depositing the electrode modification layer, and the quantum dot light-emitting diode E is prepared by using the same light-emitting diode preparation method as Example 1.

### Comparative Example 1

Compared with Example 1, in this comparative example, the S34 in Example 1 is omitted, and 100 nm Au is deposited on the electron transport layer formed by S33 to obtain the cathode, and the quantum dot light-emitting diode DB1 is obtained after packaging.

### Comparative Example 2

Compared with Example 2, in this comparative example, the S34 in Example 2 is omitted, and 100 nm Al is deposited on the electron transport layer formed by S33 to obtain the cathode, and the quantum dot light-emitting diode DB1 is obtained after packaging.

### Comparative Example 3

Compared with Example 2, in this comparative example, the electrode modification layer solution is prepared by the following methods:

according to the same ratio of carbofuran compound L1 to ethanol as in Example 1, the carbofuran compound L1 was added into ethanol, stirred at 80° C. for 2 hours, cooled to room temperature, and the precipitate was filtered to obtain a clear filtrate, which was the electrode modification layer solution.

Taking the electrode modification layer solution obtained above as the solution for depositing the electrode modification layer, the quantum dot light-emitting diode DB3 was prepared by using the same light-emitting diode preparation method as that of Example 1.

### Comparative Example 4

Compared with Example 1, in this comparative example, the electrode modification layer solution is prepared by the following methods: adding the carbolong compound L1 and the heteromacrocyclic compound Q1 prepared above into ethanol according to the molar ratio of 1:4, stirring at 100° C. for 1 h, cooling to room temperature, and filtering the precipitate to obtain a clear filtrate, which is the electrode modification layer solution.

Taking the electrode modification layer solution obtained above as the solution for depositing the electrode modification layer, the quantum dot light-emitting diode DB4 was prepared by using the same light-emitting diode preparation method as that of Example 1.

### Comparative Example 5

Compared with example 1, in this comparative example, the electrode modification layer solution is prepared by the following methods: adding the carbolong compound L1 and the heteromacrocyclic compound Q1 prepared above into ethanol according to the molar ratio of 1:0.5, stirring at 100° C. for 1 h, cooling to room temperature, and filtering the precipitate to obtain a clear filtrate, which is the electrode modification layer solution.

Taking the electrode modification layer solution obtained above as the solution for depositing the electrode modification layer, the quantum dot light-emitting diode DB5 was prepared by using the same light-emitting diode preparation method as that of Example 1.

The performance tests of the quantum dot light-emitting diodes prepared by the above examples 1˜5 and the comparative examples 1˜5 are tested, and the test results are shown in Table 1.

TABLE 1

| | UPS tests the metal | Opening | External quantum |
|---|---|---|---|
| | electrode layer | voltage | efficiency (EQE) |
| | function (eV) | (V) | (%) |
| Example 1 | 4.26 | 1.87 | 15.2% |
| Example2 | 3.26 | 1.56 | 16.2% |
| Example3 | 4.21 | 1.89 | 15.0% |
| Example4 | 4.25 | 2.2 | 18.6% |
| Example5 | 4.54 | 2.1 | 14.2% |
| Comparative | 5.3 | 2.2 | 13.5% |
| example1 | | | |
| Comparative | 4.28 | 1.92 | 13.0% |
| example2 | | | |
| Comparative | 3.52 | 1.75 | 9.2% |
| example3 | | | |
| Comparative | 4.79 | 2.94 | 7.7% |
| example4 | | | |
| Comparative | 5.0 | 2.82 | 3.4% |
| example5 | | | |

As can be seen from Table 1, after the quantum dot light-emitting diodes provided in Examples 1˜5 of this present disclosure is equipped with an electrode modification layer based on carbolong compound and heteromacrocyclic compound, the work function of the electrode layer is significantly decreased, the opening voltage of the quantum dot light-emitting diode is also significantly decreased, and the external quantum efficiency is significantly increased. It can be seen that the electrode modification layer based on carbolong compound and heteromacrocyclic compound can effectively reduce the work function of the metal electrode, improve the energy level matching between the metal electrode and the charge transport layer of the quantum dot light-emitting diodes, reduce the voltage drop and internal resistance of the quantum dot light-emitting diode, reduce the opening voltage of the quantum dot light-emitting diode, and improve the life of the quantum dot light-emitting diode. At the same time, the electrode modification layer based on carbolong compound and heteromacrocyclic compound can also increase the charge transfer rate of the quantum dot light-emitting diode, increase the current density of the quantum dot light-emitting diode, and improve the external quantum efficiency of the quantum dot light-emitting diode.

In addition, it can be seen from Examples 1˜5 and the test data of comparative Example 3 that heteromacrocyclic compound in the electrode modification layer based on carbolong compound and heteromacrocyclic compound can not only open the molecular distance between carbolong compounds and create charge transport channels, but also further reduce the work function of metal electrodes. Further optimize the energy level matching between the metal electrode and the adjacent charge transport layer, especially the electron transport layer, reduce the voltage drop and internal resistance of the quantum dot light-emitting diode, reduce the opening voltage of the quantum dot light-emitting diode, and improve the life of the quantum dot light-emitting diode.

It can also be seen from Examples 1˜5 and comparative examples 4˜5 that the ratio of carbolong compound and heteromacrocyclic compound in the electrode modification layer should not be too high or too low, and too high ratio of carbolong compound and heteromacrocyclic compound will lead to excess carbolong compound, which cannot be fully embedded in heteromacrocyclic compound, and reduce the charge transfer performance of the quantum dot light-emitting diode.

In the above-mentioned embodiments, the description of each embodiment has its own emphasis, and parts not described in detail in a certain embodiment may be referred to the related description of other embodiments.

A composite material, and a light-emitting diode and a preparation method therefor are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure.

In view of the foregoing, the content of the present specification should not be construed as limiting the disclosure.

1. A composite material, comprising:
a carbolong compound, comprising anions and cations; and
a heteromacrocyclic compound, selected from one of a substituted or unsubstituted heteroaromatic compound which has 6-20 annular atoms and is of a semi-ring structure, a substituted or unsubstituted heteroaromatic compound having 12-50 annular atoms, a dimer of a substituted or unsubstituted heteroaromatic compound having 12-50 annular atoms, and a trimer of a substituted or unsubstituted heteroaromatic compound having 12-50 annular atoms;
wherein the molar ratio of the carbolong compound to the heteromacrocyclic compound is 1:1-3.

2. The composite material according to claim 1, wherein the general chemical formula of the carbolong compound is: 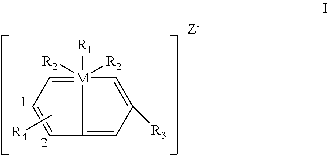
wherein in a general formula I, R₁ and R₃ are independently selected from one or more of —H, halogen, —SCN, cyanogroup, alkyl group with 1-20 carbon atoms, alkoxy group, alkylthio group, ester group, amide group, amine group, carboxyl group, substituted amide group having 2-20 carbon atoms, cycloalkyl group having 3-20 carbon atoms, substituted or unsubstituted aryl group, and substituted or unsubstituted alkenyl group having 2-20 carbon atoms, substituted or unsubstituted alkynyl group having 2-20 carbon atoms, an aryl oxygen group having 6-20 carbon atoms, and an aryl sulfur group having 6-20 carbon atoms;
R₂ is independently selected from one of the —H, quaternary phosphine groups having 3-30 carbon atoms, and pyridinyl groups having 6-7 carbon atoms;
R₄ is selected from one or more of substituted or unsubstituted aryl groups, substituted or unsubstituted alkenyl groups having 2-20 carbon atoms, substituted or unsubstituted alkynyl groups having 2-20 carbon atoms, 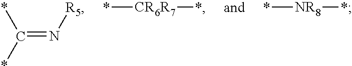
wherein, when the group represented by the R₄ contains two linking sites, the R₄ is ringed with two carbon atoms shown by 1 to 2 in formula I;
R₅, R₆, and R₇ are independently selected from one or more of —H, halogen, —SCN, cyanogroup, alkyl group having 1-20 carbon atoms, alkoxy group, alkylthio group, ester group, amide group, amine group, carboxyl group, substituted amide group having 2-20 carbon atoms, cycloalkyl group having 3-20 carbon atoms, substituted or unsubstituted aryl group, and substituted or unsubstituted aryl group having 2-20 carbon atoms One or more of alkenyl groups with carbon atoms, substituted or unsubstituted alkynyl groups having 2-20 carbon atoms, aryl oxygen groups having 6-20 carbon atoms, and aryl sulfur groups having 6-20 carbon atoms;
R₈ is selected from one or more of substituted or unsubstituted aryl groups, substituted or unsubstituted alkyl groups having 1-20 carbon atoms, and substituted or unsubstituted cycloalkyl groups having 3-20 carbon atoms;
R₁₅ is selected from one of substituted or unsubstituted alkyls, and substituted or unsubstituted ether groups;
M is selected from transition metal;
Z⁻ is an anion, which is specifically selected from one of BF⁻, OTf⁻, BF₄⁻, Cl⁻, Br⁻, F⁻, I⁻, CN⁻, and BrO₄⁻.

3. The composite material according to claim 2, wherein R₁ and R₃ are independently selected from one of —H, halogen, and —CO;
each time R₂ appears, it is independently selected from one of the —H, and —PPh₃;
R₄ is selected from one of

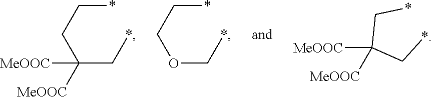

4. The composite material according to claim 2, wherein the transition metal is selected from one of iridium, osmium, and rhodium.

5. The composite material according to claim 1, wherein the heteromacrocyclic compound is m doubly symmetric compound, wherein m is an integer and m≥2.

6. The composite material according to claim 1, wherein the heteromacrocyclic compound include one or more heteroatoms selected from one of the nitrogen atoms, sulfur atoms, and oxygen atoms.

7. The composite material according to claim 1, wherein the chemical formula of heteromacrocyclic compound has one of the chemical formulas shown in formula II, III, IV, and V: 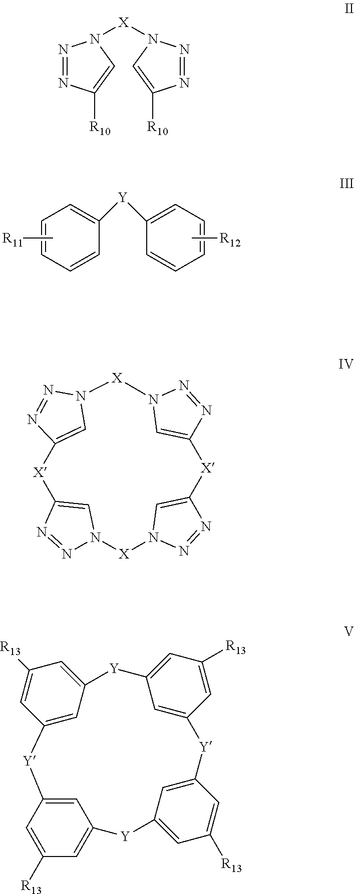
wherein the general fomular II to V, R₁₀ and R₁₃ are independently selected from one of —H, alkyl, alkoxy, and octyl-beta-d-thiopyranoside groups;
R₁₁ and R₁₂ are selected from one of —H, alkyl, alkoxy, and octyl-β-D-thiopyranoside groups; wherein R₁₁ and R₁₂ are the same group, and the connection of R₁₁ and R₁₂ makes Formula III symmetrical;
X and X′ are independently selected from one of substituted or unsubstituted aryl groups, and substituted or unsubstituted pyridine groups; and
Y is selected from one of the substituted or unsubstituted pyridine group, and 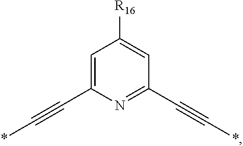
wherein R₁₆ is selected from one of —H, methoxy, and tert-butoxy groups;
Y′ is an alkyne group having two carbon atoms.

8. The composite material according to claim 7, wherein the alkyl groups in R₁₀, R₁₁, R₁₂ and R₁₃ are independently selected from one of methyl groups, and tert-butyl groups; and
the alkoxy groups in R₁₀, R₁₁, R₁₂ and R₁₃ are independently selected from one of the methoxy, and tert-butoxy groups.

9. The composite material according to claim 7, wherein the X and X′ are selected from one of 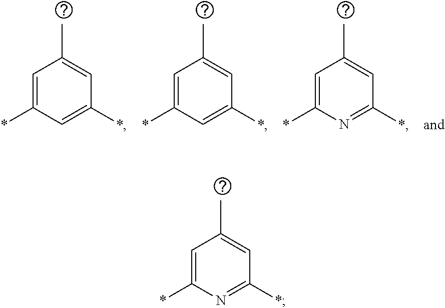
and
Y is selected from one of

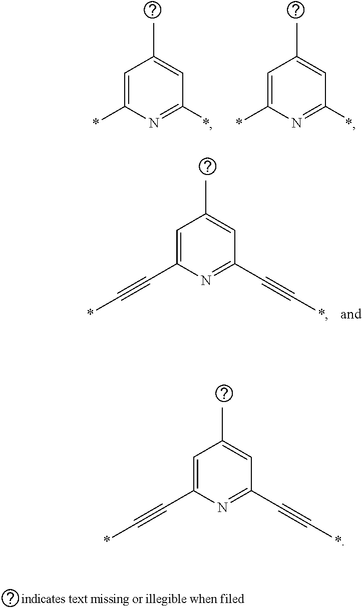

10. The composite material according to claim 1, wherein the carbolong compound is selected from one of

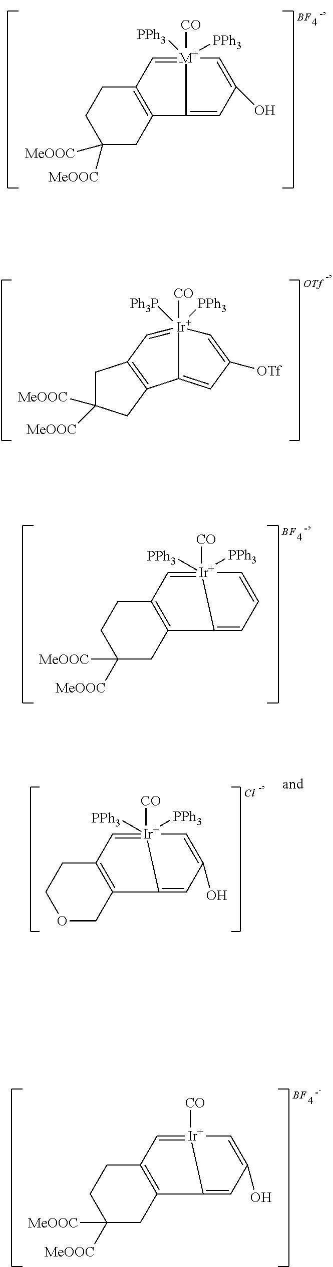

11. The composite material according to claim 1, wherein the heteromacrocyclic compound is selected from one of

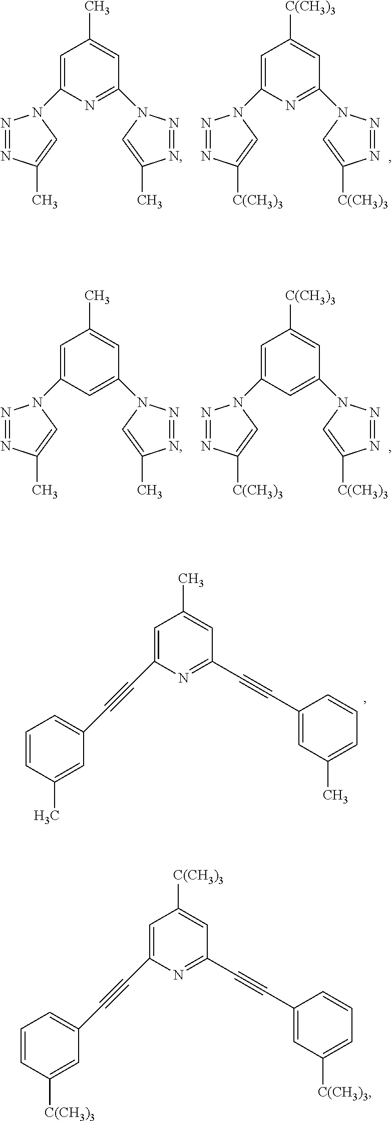

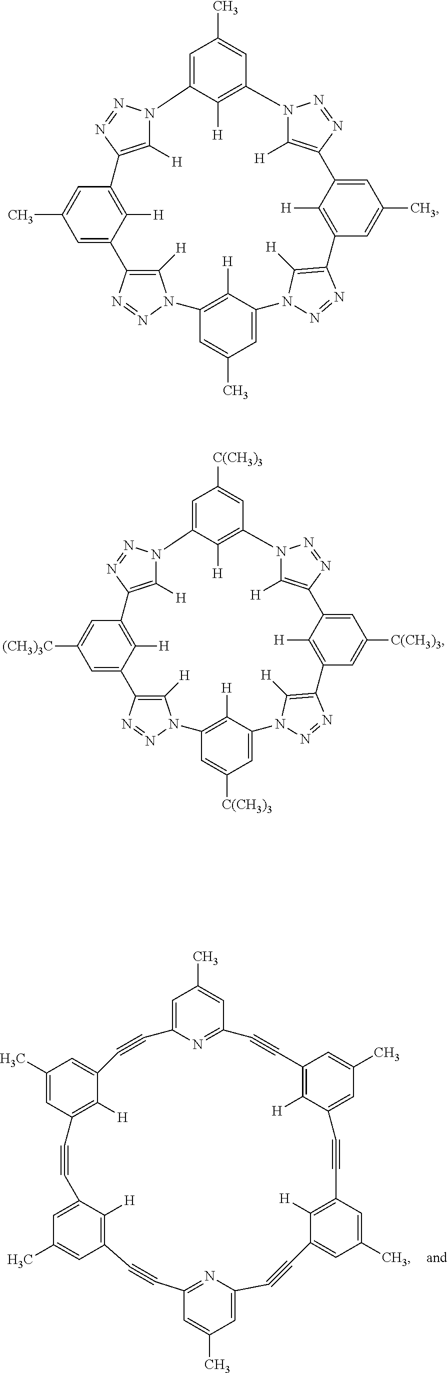 [SMILES: Cc1cc2cc(c1)-c1cn(nn1)-c1cc(C)cc(c1)-n1cc(nn1)-c1cc(C)cc(c1)-c1cn(nn1)-c1cc(C)cc(c1)-n1cc-2nn1 ; CC(C)(C)c1cc2cc(c1)-c1cn(nn1)-c1cc(cc(C(C)(C)C)c1)-n1cc(nn1)-c1cc(cc(C(C)(C)C)c1)-c1cn(nn1)-c1cc(cc(C(C)(C)C)c1)-n1cc-2nn1 ; Cc1cc2c#cc3cc(C)cc(c#cc4cc(C)cc(c#cc5cc(C)cc(c#cc6cc(C)cc(c#cc7cc(C)cc(c#cc(c1)c2)n7)c6)c5)n4)c3]

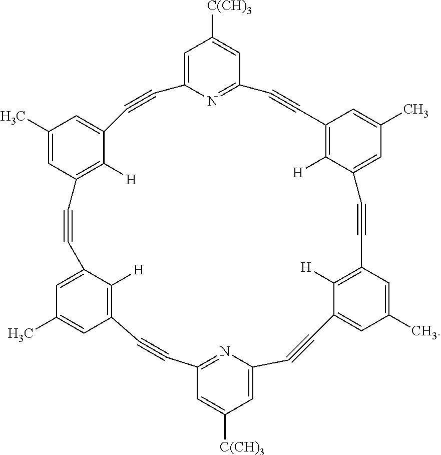

12. A dot light emitting diode, comprising:
an electrode layer;
an electrode modification layer; and
a charge transport layer arranged in layers, wherein the electrode layer, the electrode modification layer, and the charge transport layer are laminated, and the modification layer is located between the electrode layer and the charge transport layer; and wherein the material of the electrode modification layer is made of the composite material as claimed in claim 1.

13. The dot light emitting diode according to claim 12, wherein a work function of the material in the electrode layer is higher than the work function of the material in the charge transport layer.

14. The dot light emitting diode according to claim 12, wherein the electrode layer is a metal electrode layer.

15. The dot light emitting diode according to claim 12, wherein a material of the charge transport layer is selected from one or more of ZnO, TiO₂, ZrO₂, HfO₂, SrTiO₃, BaTiO₃, MgTiO₃, Alq₃, Almq₃, DVPBi, TAZ, OXD, PBD, BND, PV, TFB, MoO₃, WO₃, NiO, V₂O₅, CuO, P-type gallium nitride, CrO₃, TPD, NPB, PVK, CBP, Spiro-TPD, and Spiro-NPB.

16. The dot light emitting diode according to claim 12, wherein a material of the metal electrode layer is selected from one or more of Au, Ag, Al, Cu, and Pt.

17. The dot light emitting diode according to claim 12, wherein the dot light emitting diode further comprises a light-emitting layer arranged with the electrode layer, the electrode modification layer, and the charge transport layer; the light-emitting layer is arranged on a side of the charge transport layer away from the electrode layer; and wherein a material of the light-emitting layer comprises quantum dots and surface ligands containing a sulfhydryl group connected on the surface of the quantum dots.

18. The dot light emitting diode according to claim 17, wherein the surface ligands containing sulfhydryl groups are selected from one or more of thioglycolic acid, mercaptopropionic acid, mercaptobutyric acid, mercaptooleic acid, mercaptoglycerol, mercaptoethylamine, mercaptooleamine, and glutathione.

19. The dot light emitting diode according to claim 17, wherein the quantum dots are selected from one or more of the group IV semiconductor nanocrystals, group II-V semiconductor nanocrystals, group II-VI semiconductor nanocrystals, group IV-VI semiconductor nanocrystals, and group III-V semiconductor nanocrystals.

20. A light-emitting diode preparation method, comprising:
providing a substrate; and
forming a stacked electrode layer, an electrode modification layer and a charge transport layer in sequence on the substrate; wherein the electrode modification layer is arranged between the electrode layer and the charge transport layer;
wherein a material of the electrode modification layer is made of the composite material as claimed in claim 1.
